(19) United States
(12) Patent Application Publication
(10) Pub. No.: US 2026/0135520 A1
(43) Pub. Date: May 14, 2026

(54) CIRCUITS AND METHODS FOR BIASING OF LOW NOISE AMPLIFIERS

(71) Applicant: Skyworks Solutions, Inc., Irvine, CA (US)

(72) Inventors: Florinel G. Balteanu, Irvine, CA (US); Luan Zhang, Irvine, CA (US); Sruthi Venimadhavan, Irvine, CA (US); Ashish Vijay Pingale, Kanata (CA); Yunyoung Choi, Irvine, CA (US)

(21) Appl. No.: 19/386,125

(22) Filed: Nov. 11, 2025

Related U.S. Application Data
(60) Provisional application No. 63/719,584, filed on Nov. 12, 2024.
(60) Provisional application No. 63/719,577, filed on Nov. 12, 2024.
(60) Provisional application No. 63/719,580, filed on Nov. 12, 2024.

(51) Int. Cl. H03F 1/26; H03F 3/24

(52) U.S. Cl. CPC H03F 1/26; H03F 3/245; H03F 2200/294; H03F 2200/451

(57) ABSTRACT

A low noise radio frequency amplifier circuit including at least one amplification transistor and a slope setting circuit configured to generate an intermediate voltage based on a gain mode of the low noise amplifier circuit. The intermediate voltage has a first gradient and proportional to absolute temperature when the low noise amplifier circuit is in a first gain mode, and the intermediate voltage has a rate of change with respect to temperature smaller than the first gradient when the low noise amplifier circuit is in a second gain mode. The second gain mode has a lower gain than the first gain mode. The amplifier circuit further includes a biasing circuit configured to generate a bias voltage for the amplification transistor based on the intermediate voltage.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of the invention relate to radio frequency (RF) electronics systems, and in particular to low noise amplifiers (LNAs) and related biasing circuits.

### Description of Related Technology

A low noise amplifier (LNA) can be used to boost the amplitude of a relatively weak radio frequency (RF) signal received via an antenna. Thereafter, the boosted RF signal can be used for a variety of purposes, including, for example, driving a mixer, and/or a filter in an RF communication system.

Examples of RF communication systems with one or more LNAs include, but are not limited to, mobile phones, tablets, base stations, network access points, customer-premises equipment (CPE), laptops, and wearable electronics.

LNAs can be included in RF communication systems to amplify signals of a wide range of frequencies. For example, an LNA can be used to provide low noise amplification to RF signals in a frequency range of about 400 MHz to 300 GHz, such as in the range of about 400 MHz to about 7.125 GHz for Frequency Range 1(FR 1 ) of the Fifth Generation (5G) communication standard or in the range of about 24.250 GHz to about 71.000 GHz for Frequency Range 2(FR 2 ) of the 5G communication standard.

In typical LNAs, the gain provided by the LNA scales approximately with the current passing through the amplifying transistor of the LNA divided by the thermal voltage (which scales proportionally to absolute temperature). Therefore in order for the LNA to provide a constant gain when temperature varies, the current passing through the amplifying transistor of the LNA must be proportional to absolute temperature (PTAT), in order to cancel out the temperature factor of the thermal voltage. To achieve this LNAs have typically been biased with a PTAT signal. Specifically, a bias voltage that is proportional to absolute temperature is typically applied to the gate terminal of the amplifying transistor in an LNA.

### SUMMARY

According to one embodiment there is provided a low noise amplifier circuit. The low noise amplifier circuit comprises: at least one amplification transistor configured to amplify a radio frequency input signal; a slope setting circuit configured to generate an intermediate voltage based on a gain mode of the low noise amplifier circuit, the intermediate voltage having a first gradient and being proportional to absolute temperature when the low noise amplifier circuit is in a first gain mode, and the intermediate voltage having a rate of change with respect to temperature smaller than the first gradient when the low noise amplifier circuit is in a second gain mode, the second gain mode having a lower gain than the first gain mode; and a biasing circuit configured to generate a bias voltage for the amplification transistor based on the intermediate voltage.

In one example, the intermediate voltage sets the temperature dependence of the bias voltage.

In one example, the intermediate voltage is constant with respect to temperature when the low noise amplifier circuit is in the second gain mode.

In one example, the slope setting circuit receives at a first input a first voltage that is proportional to absolute temperature and receives at a second input a second voltage that is constant with respect to temperature.

In one example, the intermediate voltage is based on the first voltage when the low noise amplifier circuit is in the first gain mode.

In one example, the intermediate voltage is based on the second voltage or a combination of the first and second voltages when the low noise amplifier circuit is in the second gain mode.

In one example, the first gain mode is a gain mode in which a current passing through the amplification transistor of the low noise amplifier circuit remains above a threshold current value within an operating temperature range of the low noise amplifier circuit when biased by a proportional to absolute temperature bias signal.

In one example, the second gain mode is a gain mode in which a current passing through the amplification transistor of the low noise amplifier circuit falls below a threshold current value within an operating temperature range of the low noise amplifier circuit if biased by a proportional to absolute temperature bias signal.

In one example, the second gain mode is a gain mode in which the amplification of the radio frequency input signal caused by the low noise amplifier circuit is between 0 and 5 dB.

In one example, the first gain mode is a gain mode in which the amplification of the radio frequency input signal caused by the low noise amplifier circuit is above 5 dB.

In one example, the present gain mode of the low noise amplifier circuit is controlled by a gain control signal input into the biasing circuit.

In one example, a change in the present gain mode of the low noise amplifier circuit is communicated to the slope setting circuit to adjust a switching mode in the slope setting circuit.

According to another embodiment there is provided a mobile device. The mobile device comprises: an antenna; and a front-end system that includes a low noise amplifier circuit including: at least one amplification transistor configured to amplify a radio frequency input signal; a slope setting circuit configured to generate an intermediate voltage based on a gain mode of the low noise amplifier circuit, the intermediate voltage having a first gradient and being proportional to absolute temperature when the low noise amplifier circuit is in a first gain mode, and the intermediate voltage having a rate of change with respect to temperature smaller than the first gradient when the low noise amplifier circuit is in a second gain mode, the second gain mode having a lower gain than the first gain mode; and a biasing circuit configured to generate a bias voltage for the amplification transistor based on the intermediate voltage.

In one example, the intermediate voltage sets the temperature dependence of the bias voltage.

According to another embodiment there is provided a method of biasing a low noise amplifier. The method of biasing a low noise amplifier comprises: generating a bias voltage signal that is proportional to absolute temperature with a first gradient when the low noise amplifier is in a first gain mode; generating a bias voltage signal having a rate of change with respect to temperature smaller than the first gradient when the low noise amplifier is in a second gain mode, the second gain mode having a lower gain than the first gain mode; inputting the bias voltage signal into a gate terminal of an amplification transistor in the low noise amplifier.

In one example, generating the bias voltage signal includes generating an intermediate voltage and setting the temperature dependence of the bias voltage signal based on the intermediate voltage.

In one example, the generated bias voltage signal is constant with respect to temperature when the low noise amplifier circuit is in the second gain mode.

In one example, the first gain mode is a gain mode in which a current passing through the amplification transistor of the low noise amplifier circuit remains above a threshold current value within an operating temperature range of the low noise amplifier circuit when biased by a proportional to absolute temperature bias signal.

In one example, the second gain mode is a gain mode in which a current passing through the amplification transistor of the low noise amplifier circuit falls below a threshold current value within an operating temperature range of the low noise amplifier circuit if biased by a proportional to absolute temperature bias signal.

In one example, the second gain mode is a gain mode in which the amplification of the radio frequency input signal caused by the low noise amplifier circuit is between 0 and 5 dB.

According to one embodiment there is provided a low noise amplifier circuit. The low noise amplifier circuit comprises: at least one amplification transistor configured to amplify a radio frequency input signal; a slope setting circuit configured to generate an intermediate voltage based on a temperature of the low noise amplifier circuit, the intermediate voltage having a first gradient and being proportional to absolute temperature when the low noise amplifier circuit is above a threshold temperature, and the intermediate voltage having a rate of change with respect to temperature smaller than the first gradient when the low noise amplifier circuit is below the threshold temperature; and a biasing circuit configured to generate a bias voltage for the amplification transistor based on the intermediate voltage.

In one example, the intermediate voltage sets the temperature dependence of the bias voltage.

In one example, the intermediate voltage is constant with respect to temperature when the low noise amplifier circuit is below the threshold temperature.

In one example, the slope setting circuit receives at a first input a first voltage that is proportional to absolute temperature and receives at a second input a second voltage that is constant with respect to temperature.

In one example, the intermediate voltage is based on the first voltage when the low noise amplifier circuit is above the threshold temperature.

In one example, the intermediate voltage is based on the second voltage or a combination of the first and second voltages when the low noise amplifier circuit is below the threshold temperature.

In one example, the threshold temperature is a temperature at which a current passing through the amplification transistor of the low noise amplifier circuit falls below a threshold current value when biased by a proportional to absolute temperature bias signal.

In one example, the low noise amplifier circuit is configured to operate at a number of different gain modes.

In one example, the threshold temperature is different for each gain mode.

In one example, a present gain mode of the low noise amplifier circuit is controlled by a gain control signal input into the biasing circuit.

In one example, the low noise amplifier circuit further comprises a temperature measurement unit configured to output a signal indicative of the current temperature of the low noise amplifier.

In one example, the low noise amplifier circuit further comprises a comparison unit configured to compare the signal indicative of the current temperature of the low noise amplifier with the threshold temperature.

In one example, the comparison unit is configured to output a control signal to the slope setting circuit to adjust a switching mode in the slope setting circuit based on the comparison.

According to another embodiment there is provided a mobile device. The mobile device comprises: an antenna; and a front-end system that includes a low noise amplifier circuit including: at least one amplification transistor configured to amplify a radio frequency input signal; a slope setting circuit configured to generate an intermediate voltage based on a temperature of the low noise amplifier circuit, the intermediate voltage having a first gradient and being proportional to absolute temperature when the low noise amplifier circuit is above a threshold temperature, and the intermediate voltage having a rate of change with respect to temperature smaller than the first gradient when the low noise amplifier circuit is below the threshold temperature; and a biasing circuit configured to generate a bias voltage for the amplification transistor based on the intermediate voltage.

In one example, the intermediate voltage sets the temperature dependence of the bias voltage.

According to another embodiment there is provided a method of biasing a low noise amplifier. The method of biasing a low noise amplifier comprises: measuring a temperature of the low noise amplifier; generating a bias voltage signal that is proportional to absolute temperature with a first gradient when the low noise amplifier is above a threshold temperature; generating a bias voltage signal having a rate of change with respect to temperature smaller than the first gradient when the low noise amplifier is below the threshold temperature; inputting the bias voltage signal into a gate terminal of an amplification transistor in the low noise amplifier.

In one example, generating the bias voltage signal includes generating an intermediate voltage and setting the temperature dependence of the bias voltage signal based on the intermediate voltage.

In one example, the generated bias voltage signal is constant with respect to temperature when the low noise amplifier circuit is below the threshold temperature.

In one example, the threshold temperature is a temperature at which a current passing through the amplification transistor of the low noise amplifier circuit falls below a threshold current value when biased by a proportional to absolute temperature bias signal.

In one example, the threshold temperature is different for each of a number of gain modes at which the low noise amplifier circuit operates.

According to one embodiment there is provided, a biasing circuit for generating a bias voltage signal for a low noise amplifier. The biasing circuit comprises: a first voltage generation circuit configured to generate a first voltage signal that is proportional to absolute temperature; a second voltage generation circuit configured to generate a second voltage signal that is constant with respect to temperature; and a slope setting circuit configured to switch between or combine in different proportions the first voltage signal and the second voltage signal during generation of the bias voltage signal based on a present gain mode of the low noise amplifier.

In one example, the switching between or combination of the first voltage and second voltage signals sets the temperature dependence of the bias voltage signal.

In one example, the slope setting circuit is configured to output an intermediate voltage signal formed solely from the first voltage signal when in a first gain mode.

In one example, the first gain mode is a high gain mode in which a current passing through an amplification transistor of the low noise amplifier remains above a threshold current value within an operating temperature range of the low noise amplifier when biased by a proportional to absolute temperature bias signal.

In one example, the slope setting circuit is configured to output an intermediate voltage signal formed solely from the second voltage signal or having components from both the first voltage signal and the second voltage signal when in a second gain mode.

In one example, the second gain mode is a low gain mode in which a current passing through an amplification transistor of the low noise amplifier falls below a threshold current value within an operating temperature range of the low noise amplifier if biased by a proportional to absolute temperature bias signal.

In one example, the second voltage signal is generated based on a bandgap voltage reference.

In one example, the biasing circuit further comprises at least one controllable current mirror configured to introduce gain to an intermediate voltage output by the slope setting circuit during generation of the bias voltage signal based on the present gain mode.

In one example, the present gain mode of the low noise amplifier is controlled by a gain control signal input into the biasing circuit.

In one example, a change in the present gain mode of the low noise amplifier is communicated to the slope setting circuit to adjust a switching mode in the slope setting circuit to adjust the combination of or switching between the first voltage signal and second voltage signal.

In one example, the slope setting circuit combines or switches between the binary weighted combinations of the first voltage signal and the second voltage signal.

In one example, the biasing circuit further comprises a temperature measurement unit configured to output a signal indicative of the current temperature of the low noise amplifier.

In one example, the combination of or switching between the first voltage signal and the second voltage signal by the slope setting circuit is further based on the signal indicative of the current temperature of the low noise amplifier.

In one example, the slope setting circuit is configured to output an intermediate voltage signal formed solely from the first voltage signal when the temperature is above a threshold temperature value for the present gain mode.

In one example, the threshold temperature is a temperature for the present gain mode at which a current passing through the amplification transistor of the low noise amplifier circuit falls below a threshold current value when biased by a proportional to absolute temperature bias signal.

In one example, the slope setting circuit is configured to output an intermediate voltage signal formed solely from the second voltage signal when the temperature falls below a threshold temperature value for the present gain mode.

In one example, the slope setting circuit is configured to output an intermediate voltage signal having components from both the first voltage signal and the second voltage signal when the temperature falls below a threshold temperature value for the present gain mode.

According to another embodiment there is provided a front-end system. The front-end system comprises: a low noise amplifier including an amplification transistor; and a biasing circuit including a first voltage generation circuit configured to generate a first voltage signal that is proportional to absolute temperature; a second voltage generation circuit configured to generate a second voltage signal that is constant with respect to temperature; and a slope setting circuit configured to switch between or combine in different proportions the first voltage signal and the second voltage signal during generation of a bias voltage signal based on a present gain mode of the low noise amplifier.

According to another embodiment there is provided a method of biasing a low noise amplifier. The method of biasing a low noise amplifier comprises: generating a first voltage signal that is proportional to absolute temperature; generating a second voltage signal that is constant with respect to temperature; generating a bias voltage signal for the low noise amplifier based on switching between or combining in different proportions the first voltage signal and the second voltage signal according to a present gain mode of the low noise amplifier; and inputting the bias voltage signal into a gate terminal of an amplification transistor in the low noise amplifier.

In one example, generating the bias voltage signal includes generating an intermediate voltage and setting the temperature dependence of the bias voltage signal based on the intermediate voltage.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4A is a schematic diagram of one example of a communication system that operates with beamforming.

FIG. 4B is a schematic diagram of one example of beamforming to provide a transmit beam.

FIG. 4C is a schematic diagram of one example of beamforming to provide a receive beam.

FIG. 5A is a schematic diagram of one embodiment of a low noise amplifier (LNA).

FIG. 5B is a schematic diagram of another embodiment of an LNA.

FIG. 5C is a schematic diagram of one embodiment of a portion of biasing circuit for an LNA.

FIG. 6A is a schematic diagram of one embodiment of an LNA current bias circuit.

FIG. 6B is a schematic diagram of one embodiment of a servo amplifier for an LNA current bias circuit.

FIG. 6C is a schematic diagram of another embodiment of a servo amplifier for an LNA current bias circuit.

FIG. 7 is a schematic diagram of one embodiment of an output match circuit for an LNA.

FIG. 8 is a schematic diagram of a portion of one embodiment of biasing circuit for an LNA.

FIG. 9 is a schematic diagram of one embodiment of a proportional to absolute temperature voltage generation unit.

FIG. 10 is a schematic diagram of one embodiment of a constant voltage generation unit.

FIG. 11 is a schematic diagram of one embodiment of a proportional to absolute temperature voltage generation unit.

FIG. 12 is a schematic diagram of one embodiment of a constant voltage generation unit.

FIG. 13 is a schematic diagram of one embodiment of a slope setting circuit for an LNA biasing circuit.

FIG. 14A is a graph showing the effect of temperature on the current through an LNA amplifying transistor when a proportional to absolute temperature bias voltage is used.

FIG. 14B is a graph showing the effect of the bias voltage in embodiments of the present disclosure on the current through an LNA amplifying transistor as temperature varies.

FIG. 15 is a schematic diagram of one embodiment of a slope setting circuit for an LNA biasing circuit.

FIG. 16 is a schematic diagram of one embodiment of a mobile device.

FIG. 17A is a schematic diagram of one embodiment of a packaged module.

FIG. 17B is a schematic diagram of a cross-section of the packaged module of FIG. 17A taken along the lines 12B-12B.

### DETAILED DESCRIPTION OF CERTAIN EMBODIMENTS

Aspects and embodiments described herein are directed to low noise amplifier circuits and biasing circuits for modifying the temperature dependency of a bias signal for an amplifying transistor of the low noise amplifier. The modification of the temperature dependency of the bias signal prevents the current passing through the amplifying transistor of the low noise amplifier from falling below a threshold current value, and thus improves the third order intercept point (IIP3) and linearity of the low noise amplifier.

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

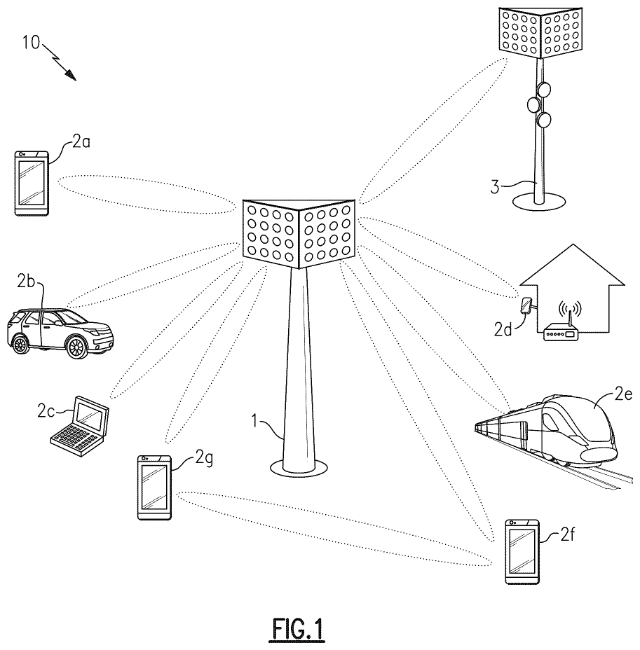

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2 e, a second mobile device 2 f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR 1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2 -2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

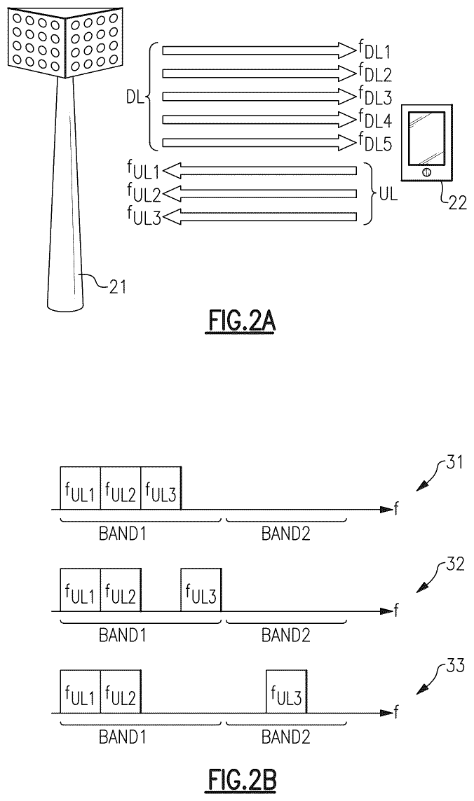

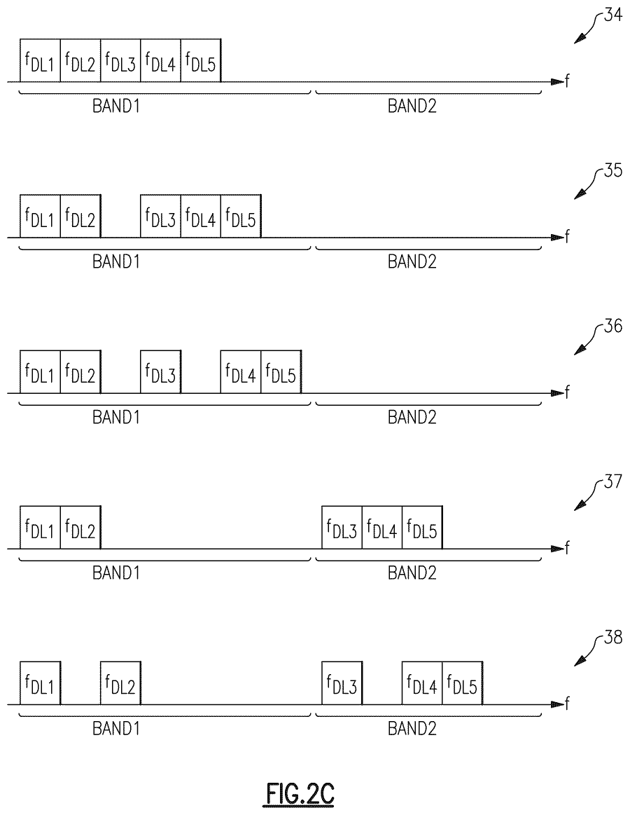

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5GHz band (5150 to 5925 MHz) and/or a 6 GHz band (5925 MHz to 7125MHz).

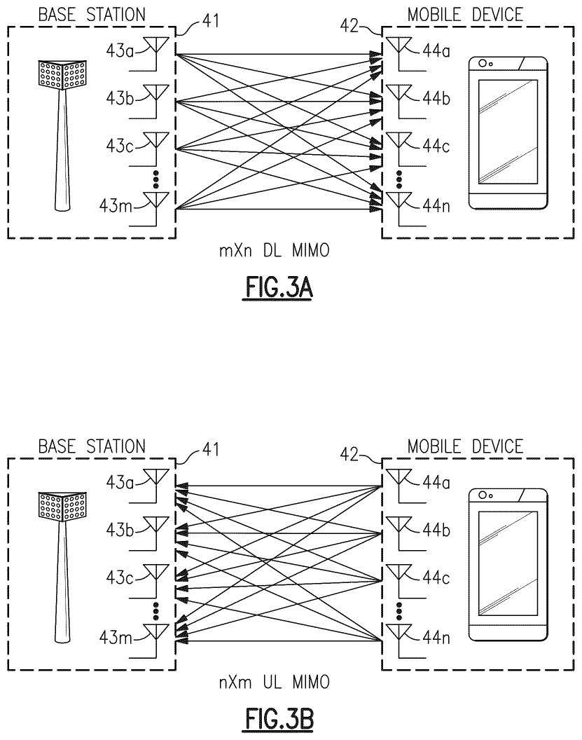

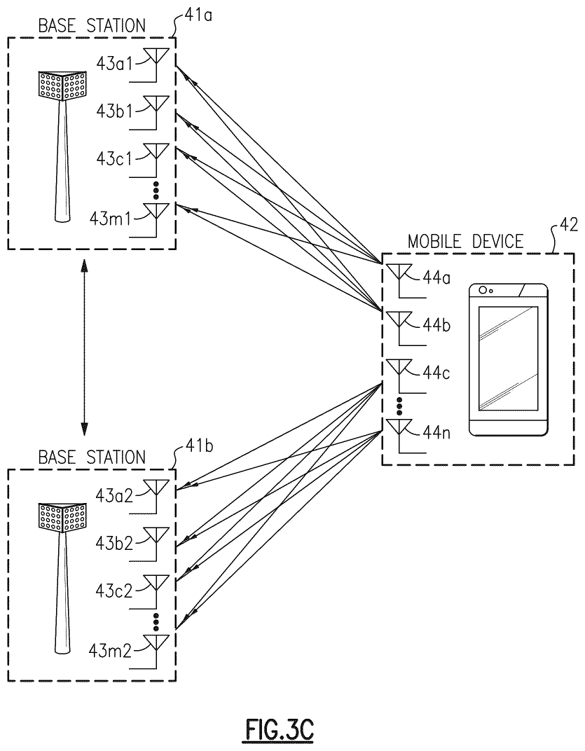

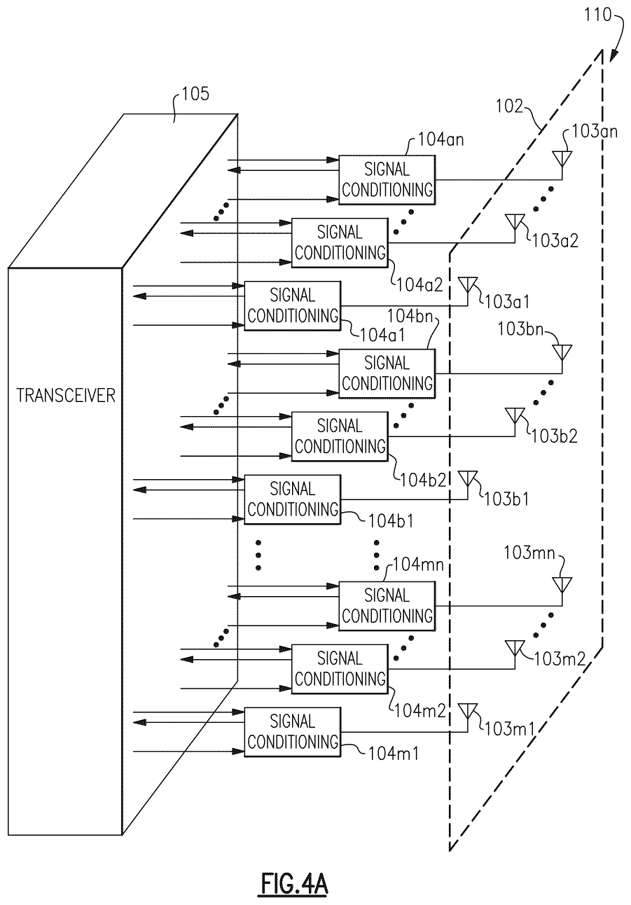

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43 a, 43 b, 43 c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

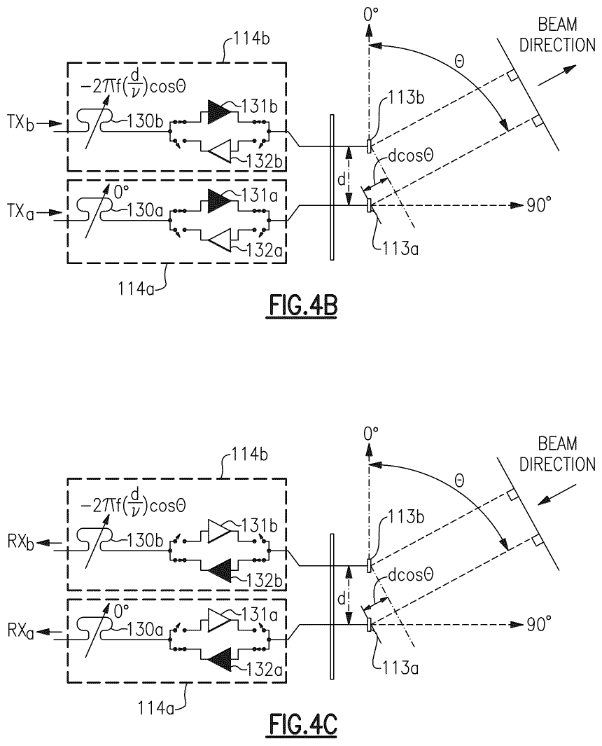

FIG. 4A is a schematic diagram of one example of a communication system 110 that operates with beamforming. The communication system 110 includes a transceiver 105, signal conditioning circuits 104a1, 104a2 . . . 104an, 104b1, 104b2 . . . 104 bn, 104m1, 104m2 . . . 104mn, and an antenna array 102 that includes antenna elements 103a1, 103a2 . . . 103an, 103b1, 103b2 . . . 103bn, 103m1, 103m2 . . . 103mn.

Communications systems that communicate using millimeter wave carriers (for instance, 30 GHz to 300 GHz), centimeter wave carriers (for instance, 3 GHz to 30 GHz), and/or other frequency carriers can employ an antenna array to provide beam formation and directivity for transmission and/or reception of signals.

For example, in the illustrated embodiment, the communication system 110 includes an array 102 of m×n antenna elements, which are each controlled by a separate signal conditioning circuit, in this embodiment. As indicated by the ellipses, the communication system 110 can be implemented with any suitable number of antenna elements and signal conditioning circuits.

With respect to signal transmission, the signal conditioning circuits can provide transmit signals to the antenna array 102 such that signals radiated from the antenna elements combine using constructive and destructive interference to generate an aggregate transmit signal exhibiting beam-like qualities with more signal strength propagating in a given direction away from the antenna array 102.

In the context of signal reception, the signal conditioning circuits process the received signals (for instance, by separately controlling received signal phases) such that more signal energy is received when the signal is arriving at the antenna array 102 from a particular direction. Accordingly, the communication system 110 also provides directivity for reception of signals.

The relative concentration of signal energy into a transmit beam or a receive beam can be enhanced by increasing the size of the array. For example, with more signal energy focused into a transmit beam, the signal is able to propagate for a longer range while providing sufficient signal level for RF communications. For instance, a signal with a large proportion of signal energy focused into the transmit beam can exhibit high effective isotropic radiated power (EIRP).

In the illustrated embodiment, the transceiver 105 provides transmit signals to the signal conditioning circuits and processes signals received from the signal conditioning circuits. As shown in FIG. 4A, the transceiver 105 generates control signals for the signal conditioning circuits. The control signals can be used for a variety of functions, such as controlling the gain and phase of transmitted and/or received signals to control beamforming.

FIG. 4B is a schematic diagram of one example of beamforming to provide a transmit beam. FIG. 4B illustrates a portion of a communication system including a first signal conditioning circuit 114a, a second signal conditioning circuit 114b, a first antenna element 113a, and a second antenna element 113b.

Although illustrated as included two antenna elements and two signal conditioning circuits, a communication system can include additional antenna elements and/or signal conditioning circuits. For example, FIG. 4B illustrates one embodiment of a portion of the communication system 110 of FIG. 4A.

The first signal conditioning circuit 114a includes a first phase shifter 130a, a first power amplifier 131a, a first low noise amplifier (LNA) 132a, and switches for controlling selection of the power amplifier 131a or LNA 132a. Additionally, the second signal conditioning circuit 114b includes a second phase shifter 130b, a second power amplifier 131b, a second LNA 132b, and switches for controlling selection of the power amplifier 131b or LNA 132b.

Although one embodiment of signal conditioning circuits is shown, other implementations of signal conditioning circuits are possible. For instance, in one example, a signal conditioning circuit includes one or more band filters, duplexers, and/or other components.

In the illustrated embodiment, the first antenna element 113a and the second antenna element 113b are separated by a distance d. Additionally, FIG. 4B has been annotated with an angle θ, which in this example has a value of about 90° when the transmit beam direction is substantially perpendicular to a plane of the antenna array and a value of about 0° when the transmit beam direction is substantially parallel to the plane of the antenna array.

By controlling the relative phase of the transmit signals provided to the antenna elements 113a, 113b, a desired transmit beam angle θ can be achieved. For example, when the first phase shifter 130a has a reference value of 0°, the second phase shifter 130b can be controlled to provide a phase shift of about −2πf(d/ν)cosθ radians, where f is the fundamental frequency of the transmit signal, d is the distance between the antenna elements, ν is the velocity of the radiated wave, and π is the mathematic constant pi.

In certain implementations, the distance d is implemented to be about ½λ, where λ is the wavelength of the fundamental component of the transmit signal. In such implementations, the second phase shifter 130b can be controlled to provide a phase shift of about −πcosθ radians to achieve a transmit beam angle θ.

Accordingly, the relative phase of the phase shifters 130a, 130b can be controlled to provide transmit beamforming. In certain implementations, a baseband processor and/or a transceiver (for example, the transceiver 105 of FIG. 4A) controls phase values of one or more phase shifters and gain values of one or more controllable amplifiers to control beamforming.

FIG. 4C is a schematic diagram of one example of beamforming to provide a receive beam. FIG. 4C is similar to FIG. 4B, except that FIG. 4C illustrates beamforming in the context of a receive beam rather than a transmit beam.

As shown in FIG. 4C, a relative phase difference between the first phase shifter 130a and the second phase shifter 130b can be selected to about equal to −2πf(d/ν)cosθ radians to achieve a desired receive beam angle θ. In implementations in which the distance d corresponds to about ½λ, the phase difference can be selected to about equal to −πcosθ radians to achieve a receive beam angle θ.

Although various equations for phase values to provide beamforming have been provided, other phase selection values are possible, such as phase values selected based on implementation of an antenna array, implementation of signal conditioning circuits, and/or a radio environment.

### Examples of LNAs and LNA Biasing

Apparatus and methods for biasing of LNAs are provided herein. In certain embodiments, an LNA includes at least one transistor that amplifies a radio frequency (RF) input signal, and a biasing circuit that generates at least one input bias voltage for the at least one transistor.

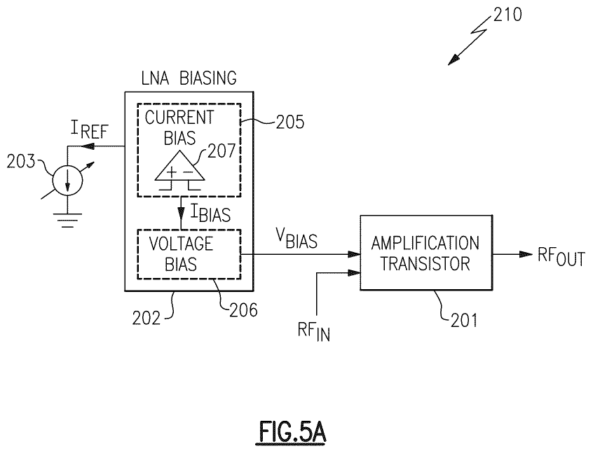

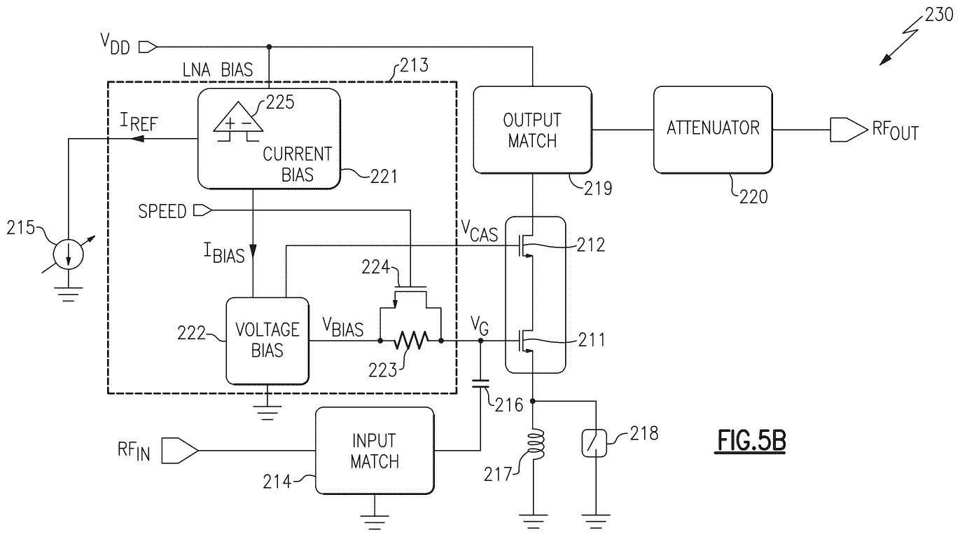

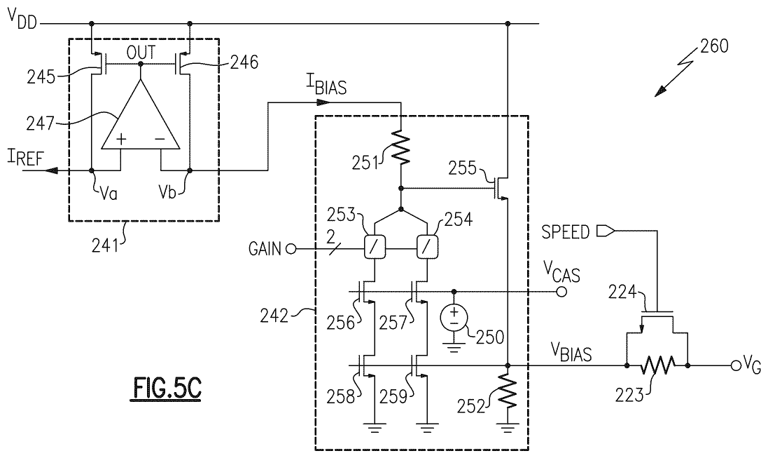

FIG. 5A is a schematic diagram of one embodiment of an LNA 210. The LNA 210 includes an amplification transistor 201, a biasing circuit 202, and a reference current source 203. In some embodiments the reference current source 203 may be considered a part of the biasing circuit 202.

As shown in FIG. 5A, the amplification transistor 201 amplifies an RF input signal RF_{IN} to generate an RF output signal RF_{OUT}. Additionally, the amplification transistor 201 is biased by a bias voltage V_{BIAS} generated by the biasing circuit 202. Although shown as including one amplification transistor 201, the LNA 210 can include one or more additional transistors that amplify the RF input signal RF_{IN}. For instance, in one example the LNA 210 is implemented as a cascode amplifier including a common-source transistor biased by a first bias voltage and a cascode transistor biased by a second bias voltage. In some embodiments, the at least one amplification transistor may include a common source transistor, and the at least one input bias voltage includes a gate bias voltage for the common source transistor.

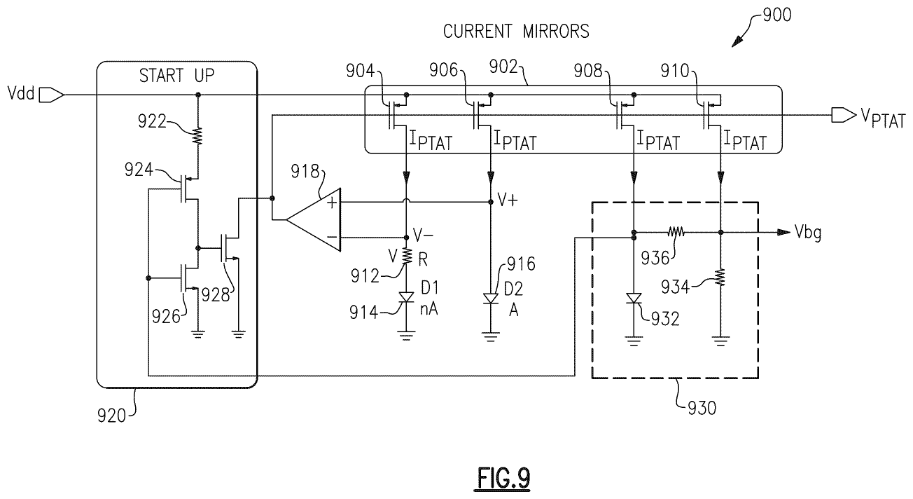

The reference current source 203 generates a reference current I_{REF} that is provided to the biasing circuit 202. The reference current source 203 is controllable in this example. For instance, in one example the reference current I_{REF} is digitally controllable to provide gain control (to adjust the amount of amplification the LNA provided to the RF input signal RF_{IN}) and/or trimming to account for variation, such as process, voltage, and/or temperature (PVT) variation. Although referred to as a “reference” current herein, it is to be understood that the reference current does not need to maintain a constant value. For example, the reference current may vary with temperature, as discussed in more detail in relation to FIGS. 8 to 15.

With continuing reference to FIG. 5A, the biasing circuit 202 includes a current bias circuit 205 and a voltage bias circuit 206. The current bias circuit 205 generates a bias current I_{BIAS} based on the reference current I_{REF}, while the voltage bias circuit 206 generates the bias voltage V_{BIAS} based on the bias current I_{BIAS}.

In certain implementations, the current bias circuit 205 includes a first bias transistor that receives the reference current I_{REF}, a second bias transistor that generates the bias current I_{BIAS}, and an amplifier 207 that controls a first bias voltage of the first bias transistor to match a second bias voltage of the second bias transistor. By implementing the current bias circuit 205 in this manner, accurate matching of the bias current I_{BIAS} to the reference current I_{REF} is achieved. Moreover, such accurate matching can be achieved without the use of cascode transistors in the current bias circuit, thereby achieving smaller area and/or superior voltage headroom that permits the LNA 210 to operate at low supply voltage levels.

Furthermore, including the amplifier 207 allows the bias current I_{BIAS} to quickly reach a steady-state level after enabling the LNA 210, thereby providing the LNA 210 with fast biasing. Such speed in providing proper bias allows the LNA 210 to be quickly turned on or off, which is particularly advantageous in 5G applications associated with short time windows for transitioning between a transmit frame and a receive frame for 5G NR TDD bands.

FIG. 5B is a schematic diagram of another embodiment of an LNA 230. The LNA 230 includes a common-source field-effect transistor (FET) 211, a cascode FET 212, a biasing circuit 213, an input match circuit 214, a reference current source 215, a DC blocking capacitor 216, a degeneration inductor 217, a degeneration bypass switch 218, an output match circuit 219, and an attenuator 220. The LNA 230 receives a power supply voltage V_{DD} and a ground voltage (ground), and serves to amplify an RF input signal RF_{IN} to generate an RF output signal RF_{OUT}.

As shown in FIG. 5B, the common source FET 211 includes a gate that receives RF input signal RF_{IN} by way of the input match circuit 214 and the DC blocking capacitor 216. The gate voltage V_{G} of the common source FET 211 is also biased by a gate bias voltage V_{BIAS} from the biasing circuit 213. The degeneration inductor 217 and the degeneration bypass switch 218 are connected in parallel between a source of the common source FET 211 and ground, and serve to provide a controllable amount of source degeneration (inductive degeneration) to the common source FET 211. The cascode FET 212 is connected between the output match circuit 219 and a drain of the common source FET 211, and includes a gate biased by as cascode bias voltage V_{CAS} generated by the biasing circuit 213.

With continuing reference to FIG. 5B, the attenuator 220 provides a controllable amount of attenuation to an RF signal provided by the output match circuit 219 to generate the RF output signal RF_{OUT} of the LNA 230. In certain implementations, the attenuator 220 is implemented as a digital-step attenuator (DSA) that provides one mechanism for gain control. Although the attenuator 220 can provide some degree of gain control, other components of the LNA 230 (for instance, the reference current source 215 and/or the biasing circuit 213) also provide gain control. Thus, multiple mechanisms can be provided for controlling the amount of amplification provided by the LNA 230.

The reference current source 215 generates the reference current I_{REF}, which is provided to the biasing circuit 213, in this embodiment. The reference current source 215 is controllable, in this example. Embodiments for controlling the reference current will be discussed in more detail in relation to FIGS. 8 to 15. Again, in some embodiments the reference current source 215 may be considered to form part of the biasing circuit 213.

In the illustrated embodiment, the biasing circuit 213 includes a current bias circuit 221, a voltage bias circuit 222, a bias resistor 223, and a resistor bypass switch 224. The current bias circuit 221 generates a bias current I_{BIAS} based on the reference current I_{REF}. In some implementations, the current bias circuit 221 includes a first bias transistor that receives the reference current I_{REF}, a second bias transistor that generates the bias current I_{BIAS}, and an amplifier 225 that controls a first bias voltage of the first bias transistor to match a second bias voltage of the second bias transistor.

With continuing reference to FIG. 5B, the voltage bias circuit 222 generates a gate bias voltage V_{BIAS} and a cascode bias voltage V_{CAS} with at least the gate bias voltage V_{BIAS} being based on the bias current I_{BIAS}. The cascode bias voltage V_{CAS} is provided to the gate of the cascode FET 212. Additionally, the gate bias voltage V_{BIAS} is provided to the gate of the common source FET 211 by way of the parallel combination of the bias resistor 223 and the resistor bypass switch 224. In some implementations, both the gate bias voltage V_{BIAS} and the cascode bias voltage V_{CAS} have voltage levels that change based on the current level of the bias current I_{BIAS}.

As shown in FIG. 5B, the resistor bypass switch 224 is controlled by a speed control signal (SPEED), which can be selectively activated to reduce the amount of resistance between the voltage bias circuit 222 and the gate of the common-source FET 211. Accordingly, a resistor-capacitor (RC) time constant associated with charging or discharging the gate of the common source FET 211 can be selectively reduced by activating the speed control signal. By implementing the LNA biasing in this manner, the benefits of fast gate bias control and high biasing isolation are achieved.

FIG. 5C is a schematic diagram of one embodiment of a biasing circuit 260 (or portion thereof) for an LNA, such as the LNA 230 of FIG. 5B. The biasing circuit 260 receives a power supply voltage V_{DD}, a ground voltage, a speed control signal (SPEED), a gain control signal (GAIN), and a reference current I_{REF}. The biasing circuit 260 generates a gate bias voltage V_{BIAS}, which is used to control a gate voltage V_{G} of a common source FET. The biasing circuit 260 also generates a cascode bias voltage V_{CAS} used to bias a cascode FET.

In the illustrated embodiment, the biasing circuit 260 includes a current bias circuit 241, a voltage bias circuit 242, a bias resistor 223, and a resistor bypass switch 224. The current bias circuit 241 receives the reference current I_{REF} and generates the bias current I_{BIAS}. The current bias circuit 241 includes a first bias FET 245 that receives the reference current I_{REF}, a second bias FET 246 that generates the bias current I_{BIAS}, and a servo amplifier 247 that controls a first bias voltage Va of the first bias FET 245 to match a second bias voltage Vb of the second bias FET 246. In this embodiment, a first input (+) of the servo amplifier 247 receives the first bias voltage Va, a second input (−) of the servo amplifier 247 receives the second bias voltage Vb, and an output of the servo amplifier 247 controls the gates of the first bias FET 245 and the second bias FET 246 to provide feedback that matches the drain-to-source voltages of the first bias FET 245 and the second bias FET 246 to one another.

By including the servo amplifier 247, accurate matching of the bias current I_{BIAS} to the reference current I_{REF} is achieved. Moreover, the current bias circuit 241 has excellent voltage headroom that allows the power supply voltage V_{DD} to operate at a low voltage level. Furthermore, the servo amplifier 247 quickly sets the gate voltages of the first bias FET 245 and the second bias FET 246 to a proper biasing level, and thus provides fast biasing that allows an LNA to be quickly turned on or off, which is desirable for TDD applications with a short time windows for transitioning between a transmit frame and a receive frame.

With continuing reference to FIG. 5C, the current bias circuit 242 includes a voltage source 250, a first biasing resistor 251, a second biasing resistor 252, a first gain control switch 253, a second gain control switch 254, a first biasing FET 255, a second biasing FET 256, a third biasing FET 257, a fourth biasing FET 258, and a fifth biasing FET 259. The bias current I_{BIAS} flows through the first biasing resistor 251 to control a gate voltage of the first biasing FET 255, which provides a current that flows through the second biasing resistor 252 to set the bias voltage V_{BIAS}. The bias current I_{BIAS} also flows through the series combination of the second biasing FET 256 and the fourth biasing FET 258 and/or the series combination of the third biasing FET 257 and the fifth biasing FET 259 based on the setting of the first gain control switch 253 and the second gain control switch 254 (controlled by the gain control signal GAIN).

Although not depicted in FIG. 5C, a wide variety of biasing schemes (for instance, feedback schemes) can be used to control a voltage level of the voltage source 250 to set the gate voltage of the second biasing FET 256 and the third biasing FET 257 (and thus the cascode bias voltage V_{CAS}) based on the amount of current flowing therethrough (corresponding to I_{BIAS}).

The gate bias voltage V_{BIAS} is used to control the gate voltage V_{G} through the parallel combination of the bias resistor 223 and the resistor bypass switch 224. The resistor bypass switch 224 is controlled by the speed control signal (SPEED).

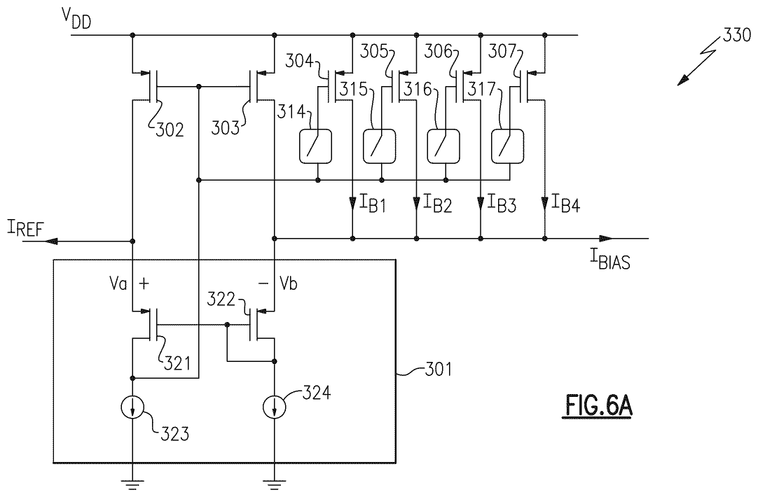

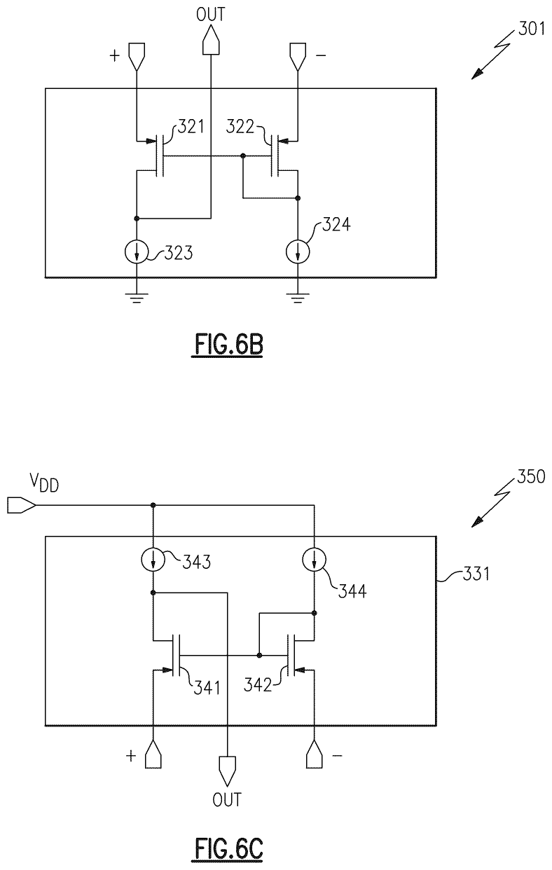

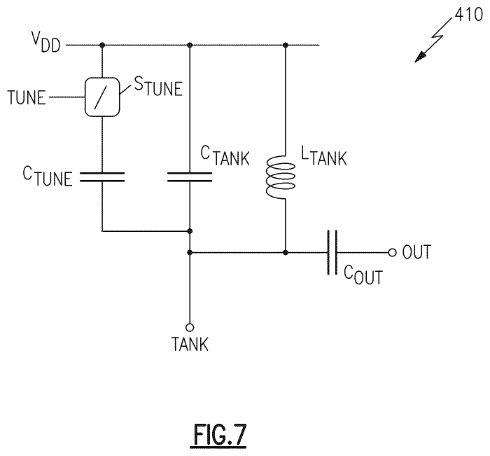

FIG. 6A is a schematic diagram of one embodiment of an LNA current bias circuit 330. The current bias circuit 330 includes a servo amplifier 301, a first biasing FET 302, a second biasing FET 303, a first selectable mirroring FET 304, a second selectable mirroring FET 305, a third selectable mirroring FET 306, a fourth selectable mirroring FET 307, a first selection switch 314, a second selection switch 315, a third selection switch 316, and a fourth selection switch 317.

As shown in FIG. 6A, the first bias FET 302 receives the reference current I_{REF}, the second bias FET 303 generates the bias current I_{BIAS}, and the servo amplifier 301 controls a first bias voltage Va of the first bias FET 302 to match a second bias voltage Vb of the second bias FET 303. Additionally, a first input (+) of the servo amplifier 301 receives the first bias voltage Va, a second input (−) of the servo amplifier 301 receives the second bias voltage Vb, and an output of the servo amplifier 301 controls the gates of the first bias FET 302 and the second bias FET 303 to provide feedback that matches the drain-to-source voltage of the first bias FET 302 to the drain-to-source voltage of the second bias FET 303.

The selectable mirroring FETs 304-307 can be selectively activated by the selection switches 314-317, respectively, to increase the bias current I_{BIAS} to provide gain control. Thus, currents I_{B1}, I_{B2}, I_{B3}, and/or I_{B4} generated by the mirroring FETs 304-307, respectively, can be selectively added to the current generated by the second bias FET 303. When activated, the selectable mirroring FETs 304-307 operate with the same gate-to-source and source-to-drain voltages as the second bias FET 303 due to the feedback provided by the servo amplifier 301.

In the illustrated embodiment, the servo amplifier 301 includes a first amplifier FET 321, a second amplifier FET 322, a first current source 323, and a second current source 324. However, other implementations are possible.

FIG. 6B is a schematic diagram of one embodiment of a servo amplifier 301 for an LNA current bias circuit. The servo amplifier 301 includes a first amplifier FET 321, a second amplifier FET 322, a first current source 323, and a second current source 324. The first amplifier FET 321 and the second amplifier FET 322 are p-type, in this example.

FIG. 6C is a schematic diagram of another embodiment of a servo amplifier 350 for an LNA current bias circuit. The servo amplifier 350 includes a first amplifier FET 341, a second amplifier FET 342, a first current source 343, and a second current source 344. The first amplifier FET 341 and the second amplifier FET 342 are n-type, in this example. The servo amplifier 350 of FIG. 6C corresponds to a complementary implementation of the servo amplifier 301 of FIG. 6B in which a transistor polarity is reversed.

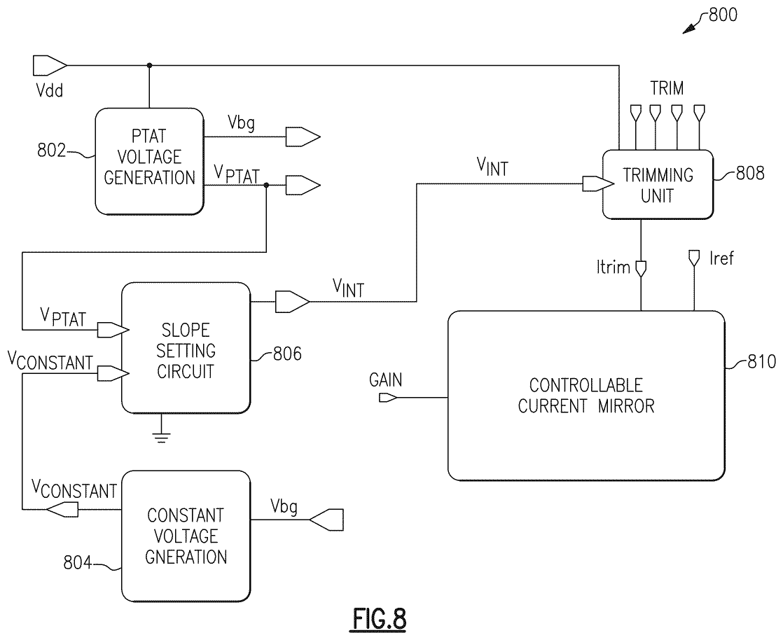

FIG. 7 is a schematic diagram of one embodiment of an output match circuit 410 for an LNA. The output match circuit 410 includes a tank capacitor C_{TANK}, a tank inductor L_{TANK}, a tuning capacitor C_{TUNE}, a tuning switch S_{TUNE}, and an output capacitor C_{OUT}. The output match circuit 410 includes a tank node TANK for connecting to one or more amplification transistors of an LNA (such as FET 212 in the embodiment of FIG. 5B), and an output node OUT for providing an output signal (such as to attenuator 220 in the embodiment of FIG. 5B).

As shown in FIG. 7, the tank capacitor C_{TANK} and the tank inductor L_{TANK} are connected in parallel between the output node OUT and a supply voltage V_{DD}. Additionally, when the tuning switch S_{TUNE} is activated (closed), the tuning capacitor C_{TUNE} is in parallel with the tank capacitor C_{TANK} to adjust the amount of tank capacitance. The output capacitor C_{OUT} is connected between the tank node TANK and the output node OUT.

### Examples of Biasing With Modified Temperature Dependency Based on Operating Conditions

As mentioned, LNAs have typically been biased with a proportional to absolute temperature (PTAT) bias voltage applied to the gate terminal of the amplifying transistor, in order to provide a constant gain as temperature varies based on the operating conditions of the LNA. To achieve this, a reference current (such as the reference current I_{REF} generated by current source 203 of FIG. 5A or current source 215 of FIG. 5B) that is proportional to absolute temperature (PTAT) is used when generating the bias voltage for the LNA.

However, using a PTAT bias voltage results in limitations in terms of the third order intercept point (IIP3), and thus linearity of the LNA. The third order intercept point is an hypothetical point where the power of third order components reaches the same level as the power of the fundamental component. It provides a measure of linearity of the LNA. In the case that a PTAT bias voltage is used, when the current passing through the amplifying transistor of the LNA becomes low, for example at a low gain mode or at a low operating temperature, the IIP3 can be negatively impacted.

Aspects and embodiments described below provide low noise amplifier circuits and biasing circuits that modifying the temperature dependency of the bias voltage for the amplifying transistor of the low noise amplifier based on the operating conditions. This modification of the temperature dependency of the bias signal prevents the current passing through the amplifying transistor from falling too low (e.g. below a threshold current value), to prevent negative effects on the IIP3 and thus the linearity of the low noise amplifier.

FIG. 8 shows an embodiment of a portion of a biasing circuit for an LNA. The biasing circuit portion 800 of FIG. 8 generates a reference current I_{REF} that may be input as the reference current in FIG. 5A or FIG. 5B. Thus the circuit of FIG. 8 may therefore also be referred to as a controllable reference current source.

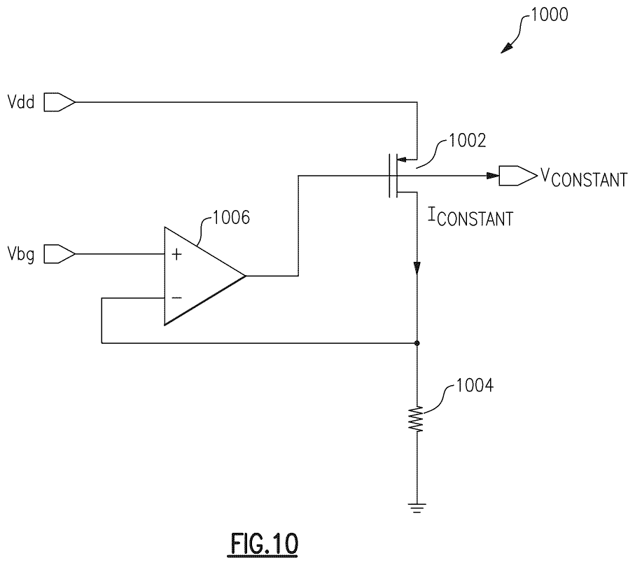

The circuit 800 of FIG. 8 includes a PTAT voltage generation unit 802 and a constant voltage generation unit 804. The PTAT voltage generation unit 802 outputs a voltage V_{PTAT} that is proportional to absolute temperature. The constant voltage generation unit 804 outputs a voltage V_{CONSTANT} that is constant with respect to temperature. Specific examples of the PTAT voltage generation unit 802 and constant voltage generation unit 804 will be described in relation to FIGS. 9 to 12.

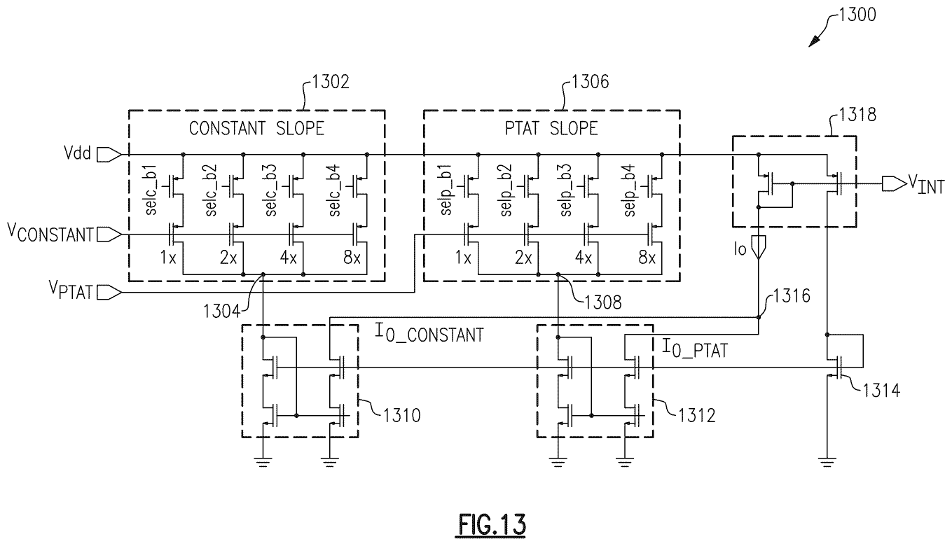

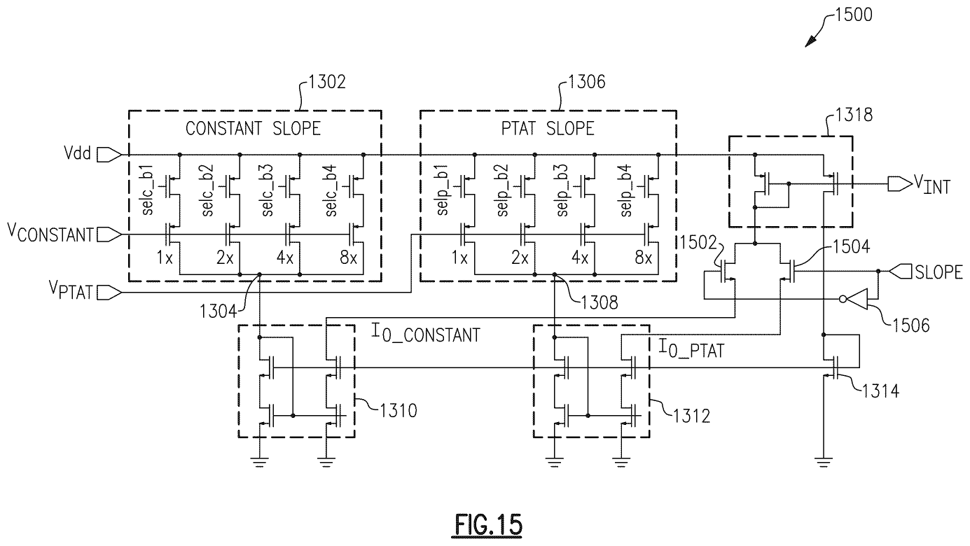

The circuit 800 of FIG. 8 further includes a slope setting circuit 806. The slope setting circuit selectively combines the V_{PTAT} and V_{CONSTANT} voltages in order to generate an intermediate voltage V_{INT}. The intermediate voltage V_{INT} may be a PTAT voltage, or a voltage that is constant with temperature, or a voltage that is a combination thereof (i.e. includes PTAT components and temperature constant components). In this way, the slope setting circuit sets the temperature dependence (including the gradient/slope with respect to temperature) of V_{INT} based on the operating conditions of the LNA (e.g. present gain mode and/or temperature of the LNA). Specific examples of the slope setting circuit 806 will be discussed in relation to FIGS. 13 and 15.

The circuit 800 of FIG. 8 further includes a trimming unit 808 and a controllable current mirror 810. Together the trimming unit 808 and controllable current mirror 810 convert the intermediate voltage V_{INT} into the reference current I_{REF}, with the temperature dependency of I_{REF} being set based on the temperature dependency of V_{INT}. Put another way, the temperature dependency of V_{INT} set by the slope setting circuit controls the temperature dependency of I_{REF}. The trimming unit 808 and controllable current mirror 810 also add gain to the intermediate voltage V_{INT} when generating I_{REF} based on a present gain mode of the LNA.

In more detail, the trimming unit 808 receives the intermediate voltage V_{INT} and outputs a trimmed current I_{TRIM} based on the intermediate voltage V_{INT}. The intermediate voltage V_{INT} is first converted to a current having the same temperature dependency as V_{INT} (for example, by using a diode). This current can then be amplified and optionally trimmed by a trimming control signal TRIM (a multi-bit digital signal, in this example) to provide enhanced accuracy when generating I_{TRIM} (e.g. by removing any errors introduced during amplification).

The trimmed current I_{TRIM} is then input into the controllable current mirror 810, which mirrors I_{TRIM} to generate the reference current I_{REF} that is provided at an output. The controllable current mirror 810 introduces a controllable gain to the mirrored current set by a gain control signal GAIN (which may again be a multi-bit digital signal, in some embodiments).

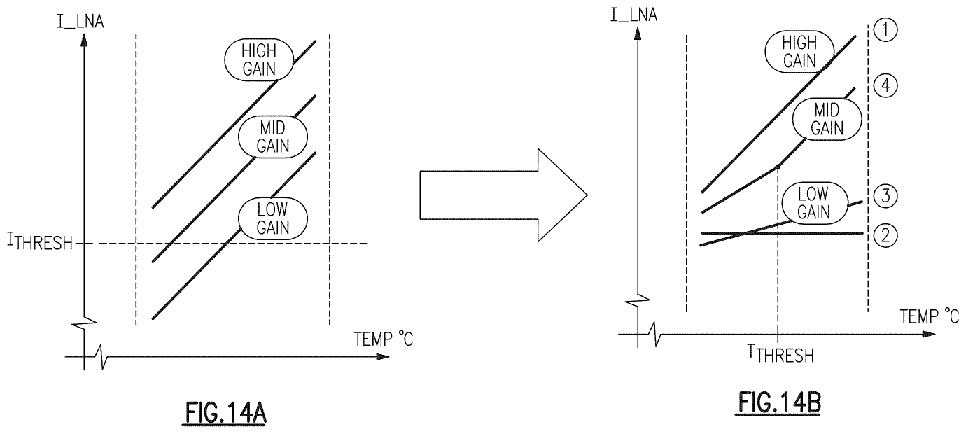

The reference current I_{REF} output by the controllable current mirror 810 may be input into the circuitry of FIG. 5A or 5B in order to control the bias voltage V_{BIAS} input into the gate of the amplifying transistor of the LNA. In this way, the temperature dependence of V_{INT} set by the slope setting circuit 806 sets the temperature dependence of V_{BIAS} via the reference current I_{REF}. Thus the temperature dependence of V_{BIAS}, and thus of the current passing through the amplifying transistor of the LNA, can be controlled by the slope setting circuit 806 in order to achieve the beneficial effects in terms of linearity and IIP3, as discussed in more detail in relation to FIG. 14B.

The gain mode of the LNA is determined, at least in part, by the gain control signal GAIN and/or the trimming control signal TRIM input into the biasing circuit via the trimming unit 808 and controllable current mirror 810. For example, in the case that the low noise amplifier is used in a mobile telephone device, when the device is close to a base station with a strong signal a low gain mode is required to avoid saturation, whereas when the device is far from the base station with a low signal a higher gain mode is required. The specific gain mode can be set based on the control signals input into the biasing circuit via the trimming unit 808 and controllable current mirror 810. Specifically, the GAIN and/or TRIM control signals set the amplification introduced to the intermediate voltage V_{INT} and reference current I_{REF}, thus modifying the gain of the LNA via the bias voltage signal V_{BIAS}.

In general, the trimming unit 808 and controllable current mirror 810 may be replaced by a single unit in some embodiments, which takes V_{INT} and produces a current having the same temperature dependence, but with gain added based on an input gain control signal (and optional trimming). In the embodiment of FIG. 8, the trimming unit 808 and controllable current mirror 810 may both include current Digital to Analog Converters (DACs), such as binary weighted current DACs. The trimming unit 808 and controllable current mirror 810 may differ in some embodiments in that the trimming unit 808 includes pFETs and the controllable current mirror 810 includes nFETs.

Further, the slope setting circuit 806 also acts to isolate trimming unit 808 from the PTAT voltage generation unit 802 and constant voltage generation unit 804 by means of one or more current mirrors within the slope setting circuit 806 (discussed in relation to FIGS. 13 and 15).

The circuit 800 of FIG. 8 in combination with the circuit shown in FIG. 5A or 5B may together be referred to as the biasing circuit of the LNA. Alternatively, just the circuit of FIGS. 5A and 5B, or those circuits but further including the trimming unit 808 and controllable current mirror 810, may be referred to as the biasing circuit for the LNA in some embodiments.

FIG. 9 shows one embodiment of a PTAT voltage generation unit 900, which may be used as the PTAT voltage generation unit 802 of FIG. 8. The PTAT voltage generation unit 900 includes a multi-transistor current mirror 902 including a first FET 904, and second FET 906, a third FET 908 and a fourth FET 910. Each of the FETs of the multi-transistor current mirror 902 receives a supply voltage Vdd. The first FET 904 is connected to ground via a first resistor 912 and a first diode 914. The second FET 906 is connected to ground by a second diode 916. The first FET 904 and second FET 906 are also connected to the non-inverting and inverting input respectively of an op amp 918. The output of the op amp 918 is fed back to the gate terminals of the first, second, third and fourth FETs. Together, the first resistor 912, first diode 914, second diode 916 and op amp 918 set a PTAT current Iptat through each of the FETs in the current mirror 902. In particular, the voltages V+ and V− at the input terminals of the op amp 918 are equal, Iptat=V/R, where R is the resistance of the first resistor 912 and V is the voltage over the first resistor 912. Further, V=(kT/q)ln(n), where kT/q is the thermal voltage (k is the Boltzmann constant, q is the charge on an electron, and T is the temperature), and n is the ratio of the interface/junction areas of the first and second diodes 914,916 (the first diode having area nA and the second diode having area A). The PTAT voltage generation unit 900 outputs a PTAT voltage V_{PTAT} based on the PTAT current Iptat. The voltage V_{PTAT} may be used as an input for the slope setting circuit 806 of FIG. 8 in some embodiments.

The PTAT voltage generation unit 900 further includes a start up unit 920 including a second resistor 922, a fifth FET 924, a sixth FET 926 and a seventh FET 928. The start up unit 920 is used when the supply voltage Vdd first comes on to ensure that the PTAT voltage generation unit 900 is in operating state.

Further, in the present embodiment the PTAT voltage generation unit 900 further includes a bandgap core 930. The bandgap core 930 includes a third diode 932 connected between the third FET 908 and ground, a third resistor 934 connected between the fourth FET 910 and ground, and a fourth resistor 936 connected between the third diode 932 and third resistor 934. The bandgap core generates and outputs a bandgap reference voltage Vbg which is constant with respect to temperature. The operation of the bandgap core 930 is described in more detail in U.S. Pat. No. 6,788,041B2, which is hereby incorporated by reference in its entirety.

FIG. 10 shows one embodiment of a constant voltage generation unit 1000 which may be used as the constant voltage generation unit 804 of FIG. 8. The embodiment of the constant voltage generation unit 1000 of FIG. 10 is to be used in conjunction with a PTAT voltage generation unit including a bandgap core, such as the PTAT voltage generation unit 900 of FIG. 9.

The constant voltage generation unit 1000 includes a first FET 1002 which receives a supply voltage Vdd at its source terminal. The drain terminal of the first FET 1002 is connected to ground by a first resistor 1004, and is also connected to the inverting input of an op amp 1006. The non-inverting input of op amp 1006 receives the bandgap voltage Vbg, for example from the bandgap core 930 of PTAT voltage generation unit 900. The output terminal of the op amp 1006 is connected to the gate terminal of the first FET 1002.

The constant voltage generation unit 1000 is configured to cause a constant with temperature current Iconstant to pass through the first FET 1002, and output a constant with temperature voltage V_{CONSTANT} at the gate terminal of the first FET 1002. The temperature constant current Iconstant is determined by the bandgap voltage Vbg divided by the resistance of the first resistor 1004. The voltage V_{CONSTANT} may be used as an input for the slope setting circuit 806 of FIG. 8 in some embodiments.

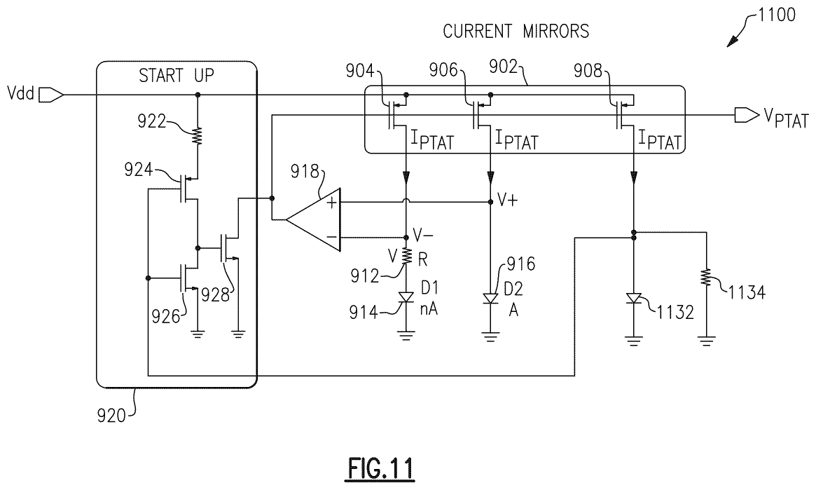

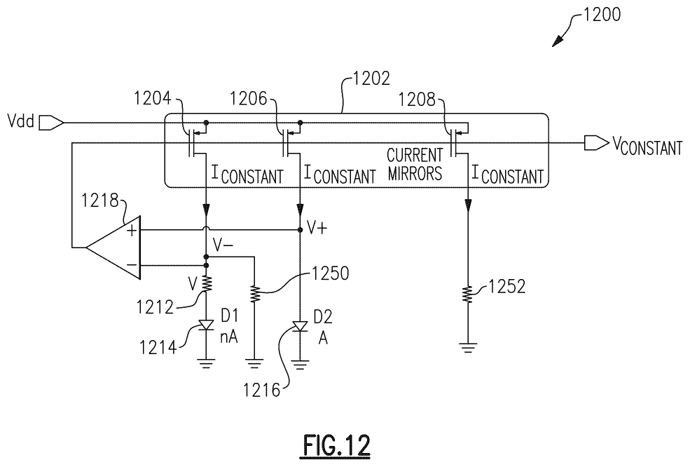

In the embodiments of FIGS. 8 to 10, the PTAT voltage generation unit 802,900 outputs an bandgap voltage Vbg, which is used by the constant voltage generation unit 804,1000 to generate the constant voltage V_{CONSTANT}. However, in other embodiments, the PTAT voltage generation unit 802 of FIG. 8 may not output a bandgap voltage Vbg to be received by the constant voltage generation unit 804. FIGS. 11 and 12 show embodiments of the PTAT voltage generation unit and constant voltage generation unit in such a case.

FIG. 11 shows an alternative embodiment of a PTAT voltage generation unit 1100, which may be used as the PTAT voltage generation unit 802 of FIG. 8. The PTAT voltage generation unit 1100 of FIG. 11 is the same as the PTAT voltage generation unit 900 of FIG. 9, except that the fourth FET 910 and the bandgap core 930 have been removed. Instead, in the PTAT voltage generation unit 1100 the third FET 908 is connected to ground via a parallel diode 1132 and resistor 1134. The PTAT voltage generation unit 1100 again outputs a PTAT voltage V_{PTAT} which may be used as an input for the slope setting circuit 806 of FIG. 8 in some embodiments.

FIG. 12 shows an alternative embodiment of a constant voltage generation unit 1200 which may be used as the constant voltage generation unit 804 of FIG. 8. The embodiment of the constant voltage generation unit 1200 of FIG. 12 is to be used in conjunction with a PTAT voltage generation unit that does not include a bandgap core, such as the PTAT voltage generation unit 1100 of FIG. 11. Put another way, in embodiments where a bandgap voltage Vbg is not available as an input for the constant voltage generation unit 804 of FIG. 8, the constant voltage generation unit 1200 may be used to provide the voltage V_{CONSTANT}.

The constant voltage generation unit 1200 includes a multi-transistor current mirror 1202 including a first FET 1204, and second FET 1206, and a third FET 1208. Each of the FETs of the multi-transistor current mirror 1202 receives a supply voltage Vdd. The first FET 1204 is connected to ground via a first resistor 1212 and a first diode 1214. The second FET 1206 is connected to ground by a second diode 1216. The first FET 1204 and second FET 1206 are also connected to the non-inverting and inverting input respectively of an op amp 1218. The output of the op amp 1218 is fed back to the gate terminals of the first, second, and third FETs.

The constant voltage generation unit 1200 further includes a second resistor 1250 connected between the inverting input of an op amp 1218 and ground. A complementary to temperature current Ictat flows through the second resistor, where Ictat=Vd2/R3 where Vd2 is the voltage over the second diode 1216 and R3 is the resistance of the second resistor 1250. This complimentary to temperature current sums with a PTAT current flowing through the first resistor 1212 and a first diode 1214 (analogous to Iptat of FIGS. 9 and 11), resulting a constant current Iconstant flowing through each of the first, second and third FETS of the current mirror 1202. The third FET 1208 is connected to ground by a third resistor 1252. The constant voltage generation unit 1200 outputs a constant voltage V_{CONSTANT} based on the constant current Iconstant. The voltage V_{CONSTANT} may be used as an input for the slope setting circuit 806 of FIG. 8 in some embodiments.

Although FIGS. 9 to 12 provide various examples of circuitry for generating the PTAT and constant voltages V_{PTAT} and V_{CONSTANT}, in general various other circuits for generating PTAT and constant voltages may be used.

FIG. 13 shows a slope setting circuit 1300 according to an embodiment of the present disclosure. The slope setting circuit 1300 may be used as the slope setting circuit 806 of FIG. 8.

The slope setting circuit includes a constant slope generation section 1302. The constant slope generation section 1302 is a binary weighted current DAC that includes four pairs of FETs connected in parallel between a supply voltage Vdd and an output node 1304. Each pair of FETs includes a first FET that receives the supply voltage Vdd at its source terminal, and receives a digital control signal selc_b1, selc_b2, selc_b3 and selc_b4 respectively at its gate terminal. The drain terminal of the first FET is connected to the source terminal of a second FET in the pair. The second FET in each pair receives at its gate terminal the constant voltage V_{CONSTANT} from the constant voltage generation unit 804. The drain terminal of the second FET of each pair is connected to the output note 1304.

In use, the constant slope generation section 1302 outputs a current I_{O_CONSTANT} that is constant with respect to temperature. The magnitude of the current I_{O_CONSTANT} is set by the digital control signals selc_b1, selc_b2, selc_b3 and selc_b4. Each control signal turns on the first FET in each pair of FETs. When the first FET is on for each branch (i.e. for each pair), a constant with temperature current component is added to the current I_{O_CONSTANT} at the output node 1304 in a binary weighted fashion. In this way, the value of the temperature independent current I_{O_CONSTANT} can be varied based on the selc_b control signals.

The slope setting circuit also includes a PTAT slope generation section 1306. The PTAT slope generation section 1306 is the same as the constant slope generation section 1302, except that the first FET of each pair receives at its gate terminal a respective digital control signal selp_b1, selp_b2, selp_b3 and selp_b4, and the second FET of each pair receives at its gate terminal the PTAT voltage V_{PTAT} from the PTAT voltage generation unit 802. The PTAT slope generation section 1306 has its own output node 1308 analogous to output node 1304 of the constant slope generation section 1302.

In use, the PTAT slope generation section 1306 outputs a current I_{O_PTAT} that is proportional to absolute to temperature. The gradient of the current I_{O_PTAT} is set by the digital control signals selp_b1, selp_b2, selp_b3 and selp_b4. Each control signal turns on the first FET in each pair of FETs. When the first FET is on for each branch (i.e. for each pair), a PTAT current component is added to the current I_{O_PTAT} at the output node 1308 in a binary weighted fashion. In this way, the gradient of the proportional to absolute temperature current I_{O_PTAT} can be varied based on the selp_b control signals.

The output node 1304 of the constant slope generation section 1302 is connected to a first current mirror 1310 which mirrors the current I_{O_CONSTANT} output by the constant slope generation section 1302. Similarly, the output node 1308 of the PTAT slope generation section 1306 is connected to a second current mirror 1312 which mirrors the current I_{O_PTAT} output by the PTAT slope generation section 1306. Each of the first and second current mirrors 1310,1312 are cascode current mirrors in the embodiment of FIG. 13, but other types of current mirror could be used in general. The cascode transistors of the first and second current mirrors 1310,1312 are biased by a transistor 1314 separate to the current mirrors in the present embodiment.

The outputs of the first and second current mirrors 1310,1312 are combined at node 1316 to form a combined current I_{O}. The combined current I_{O} therefore includes a component that is constant with respect to temperature and component that is proportional to absolute temperature, with the relative proportions of constant with temperature components and PTAT components controlled by the digital control signals selc_b1, selc_b2, selc_b3, selc_b4, selp_b1, selp_b2, selp_b3 and selp_b4. In this way, both the gradient of I_{O} with respect to temperature, and an offset by a constant current value can be controlled by the digital control signals input into the constant slope generation section 1302 and PTAT slope generation section 1306. Put another way, the gradient of a graph in the form y=mx+c, where y is the current I_{O} and x is temperature, may be controlled by the digital control signals selp_b1, selp_b2, selp_b3 and selp_b4 input into the PTAT slope generation section 1306. The y intercept of the graph in the form y=mx+c, where y is the current I_{O} and x is temperature, may be controlled by the digital control signals selc_b1, selc_b2, selc_b3, and selc_b4 input into the constant slope generation section 1302.

It is noted that in some embodiments each of the control signals selc_b1, selc_b2, selc_b3, selc_b4 may be switched off, such that the combined current I_{O} includes only components that are proportional to absolute temperature. Similarly, in some embodiments each of the control signals selp_b1, selp_b2, selp_b3, selp_b4 may be switched off, such that the combined current I_{O} includes only components that are constant with temperature.

The node 1316 is connected to an output stage 1318 that includes a first and second FET connected as a current mirror. The combined current I_{O} is input into the first FET of the current mirror of the output stage 1318, and is converted into a voltage and output by the gate of the second FET as intermediate voltage V_{INT}. The intermediate voltage V_{INT} has the same temperature dependency as the combined current I_{O}, and can be supplied to the trimming unit 808 as shown in FIG. 8.

Thus, the slope setting circuit 1300 is able to combine in different proportions V_{PTAT} and V_{CONSTANT}, or may switch entirely between V_{PTAT} and V_{CONSTANT} (i.e. only use V_{PTAT} or V_{CONSTANT} components when forming the intermediate voltage V_{INT}), based on the digital control signals selc_b1, selc_b2, selc_b3, selc_b4, selp_b1, selp_b2, selp_b3 and selp_b4. As discussed previously, the temperature dependence of intermediate voltage V_{INT} is communicated through the bias circuit to set the temperature dependence of V_{BIAS}, which in turn controls the current I_LNA flowing through the amplifying transistor (such as amplifying transistor 201 of FIG. 5A) of the LNA.

In certain embodiments, the digital control signals selc_b and selp_b may be set based on a present gain mode of the LNA (e.g. set by the GAIN and/or TRIM control signals discussed in relation to FIG. 8), as will be explained in relation to FIGS. 14A and 14B. Specifically, a change in the present gain mode of the low noise amplifier circuit is communicated to the slope setting circuit 1300 via the digital control signals, to adjust the switching of the constant slope generation section 1302 and PTAT slope generation section 1306 in the slope setting circuit 1300.

FIG. 14A is a graph showing examples of the effect of temperature on the current through an LNA amplifying transistor when a proportional to absolute temperature bias voltage is used. Specifically, FIG. 14A shows the relationship between the temperature of the LNA and the current through the amplifying transistor of the LNA (such as the amplifying transistor 201 of FIG. 5A) for three different gain modes, labeled LOW, MID and HIGH in FIG. 14A. A PTAT bias voltage is used for the plots in FIG. 14A, as would be the case if, for example, a PTAT current is used as the reference current I_{REF} in FIG. 5A.

As seen in FIG. 5A, in each gain mode the current I_LNA through the amplifying transistor increases linearly with temperature with a constant gradient. As the gain provided by the LNA scales approximately with the current passing through the amplifying transistor of the LNA divided by the thermal voltage, an LNA biased as shown in FIG. 14A will have a constant gain as temperature varies. However for certain gain modes, such as the MID and LOW gain modes shown in FIG. 14A, the current through the amplifying transistor I_LNA will drop below a threshold current value I_{THRESH} within the operating temperature range of the LNA (denoted by the vertical dashed lines in FIG. 14A). This threshold current value corresponds to when the IIP3 falls outside an acceptable range in terms of linearity. The exact value of the threshold current voltage will depend on the frequency of operation of the LNA, as well as a target value for the IIP3, however the threshold current value may be approximately 2-3 mA in some embodiments.

To prevent the current through the amplifying transistor I_LNA falling below the threshold current value I_{THRESH}, the embodiments and techniques described herein may be applied by the slope setting circuit 1300 of FIG. 13. For example, FIG. 14B shows the effect of bias voltages generated according to embodiments of the present disclosure on the relationship between temperature and current through the LNA amplifying transistor.

FIG. 14B shows a first plot (labelled 1 in FIG. 14B) for the LNA when in the HIGH gain mode. As the LNA current I_LNA remains acceptable over the entire operating temperature range of the LNA, i.e. does not drop below the threshold current value where the IIP3 moves out of an acceptable range, a PTAT bias voltage may be used when the LNA is in the HIGH gain mode. The digital control signals for the slope setting circuit 1300 will therefore be chosen such that the slope setting circuit 1300 only includes PTAT components based on V_{PTAT} when generating V_{INT}, such that the bias voltage V_{BIAS} is proportional to absolute temperature.

FIG. 14B also shows a second plot (labelled 2 in FIG. 14B) for the LNA when in the LOW gain mode. To prevent the LNA current I_LNA dropping below I_{THRESH} in the operating temperature range of the LNA (i.e. as done in FIG. 14A when the LNA was biased by a PTAT bias voltage) the bias voltage V_{BIAS} is modified by the slope setting circuit 1300. Specifically, the digital control signals for the slope setting circuit 1300 can be chosen such that the slope setting circuit 1300 only includes temperature constant components based on V_{CONSTANT} when generating V_{INT}, such that the bias voltage V_{BIAS} is constant with temperature. Thus the value of the LNA current I_LNA is also constant as temperature increases in the second plot. Although such a bias means that the gain applied to the RF signal to be amplified by the LNA may vary slightly with temperature, the negative impact of the low LNA current I_LNA on IIP3 and linearity is avoided.

FIG. 14B also shows a third plot (labelled 3 in FIG. 14B) for the LNA, again when in the LOW gain mode. To prevent the LNA current I_LNA dropping below I_{THRESH} in the operating temperature range of the LNA the bias voltage V_{BIAS} is again modified by the slope setting circuit 1300. However, in the case of the third plot, the digital control signals for the slope setting circuit 1300 are chosen such that the slope setting circuit 1300 includes both components that are constant with temperature based on V_{CONSTANT} and components that are proportional to absolute temperature based on V_{PTAT} when generating V_{INT}. The proportion of PTAT components that are used to generate V_{INT} by the slope setting circuit 1300 may be chosen such that the gradient of V_{INT} (and thus V_{BIAS} and I_LNA) with respect to temperature is lower (having a smaller rate of change with respect to temperature) compared to the HIGH gain mode where a PTAT bias voltage is used. Thus as shown by the third plot, the shallow gradient prevents the LNA current I_LNA from dropping too low (i.e. below the threshold current I_{THRESH}), and thus prevents the associated IIP3 and linearity limitations.

Thus, by controlling the slope setting circuit 1300 with suitable digital control signals, the intermediate voltage V_{INT} and thus bias voltage V_{BIAS} and LNA current I_LNA can be switched from being PTAT at high gain modes to a combination of PTAT and constant with temperature components at lower gain modes, or switch to being entirely constant with temperature at lower gain modes, in order to prevent the LNA current I_LNA becoming too low and negatively impacting the IIP3. In this way, the slope setting circuit 1300 may program the slopes of the bias voltage and LNA current temperature responses for different gain modes.

In general, the specific combination of the digital control signals selc_b1, selc_b2, selc_b3, selc_b4, selp_b1, selp_b2, selp_b3 and selp_b4 may be pre-programmed for each gain mode based on predefined factors including the desired IIP3 characteristics and corresponding threshold current, the operating frequency of the LNA, the operating temperature range and the specific LNA circuit configuration. Such pre-programed digital control signals may be stored in one or more tables, or implemented using a state machine or the like.

Whether a gain mode is high enough for a PTAT bias voltage to be suitably used may depend on a number of factors, including a target IIP3 value, the operating frequency of the LNA, the operating temperature range and the specific LNA circuit configuration. However, in some embodiments, a LOW gain mode may correspond to a gain introduced to the RF signal to be amplified of between 0 and 5 dB, and a HIGH gain mode may correspond to a gain introduced to the RF signal to be amplified of above 5 dB.

In further embodiments, rather than slope setting circuit 1300 modifying the intermediate voltage V_{INT} and thus bias voltage V_{BIAS} solely based on the gain mode of the LNA, a current operating temperature of the LNA could additionally or alternatively be taken into account when setting the temperature dependence of the bias voltage V_{BIAS}.

Specifically, the biasing circuit (such as the portion 800 shown in FIG. 8) may further include a temperature measurement unit (not shown in the Figures). The temperature measurement unit is configured to measure a current operating temperature of the LNA. Various known devices of circuits for detecting temperature of a LNA may be used for this purpose. One example of a suitable temperature sensing circuit is described in US2024/088846A1, which is hereby incorporated by reference in its entirety.

The biasing circuit may further include a comparison unit (not shown) configured to compare the temperature of the LNA measured by the temperature measurement unit with a threshold temperature value. If the measured temperature of the LNA falls below the threshold temperature value, the comparison unit can output a control signal to effect a change in the digital control signals selc_b1, selc_b2, selc_b3, selc_b4, selp_b1, selp_b2, selp_b3 and selp_b4 (i.e. to change the switching mode of the constant slope generation section 1302 and PTAT slope generation section 1306 of the slope setting circuit 1300). In some embodiments the comparison unit may be an op amp comparator or the like.

The threshold temperature may be chosen to correspond with the temperature at which the LNA current I_LNA falls below the threshold current value I_{THRESH} at which the IIP3 moves out of an acceptable range. In some embodiments the same threshold temperature may be used for a number of different gain modes of the LNA. In other embodiments, each gain mode of the LNA may have its own threshold temperature. The threshold temperature for each gain mode may be based on predefined factors including the desired IIP3 characteristics and corresponding threshold current, the operating frequency of the LNA, the operating temperature range and the specific LNA circuit configuration.

FIG. 14B also shows a fourth plot (labelled 4 in FIG. 14B) for the LNA in a MID gain mode where a temperature measurement unit is used and the current temperature of the LNA is taken into account when setting the bias voltage V_{BIAS}. When the temperature of the LNA circuit is above the threshold temperature T_{THRESH}, the digital control signals for the slope setting circuit 1300 are chosen such that the slope setting circuit 1300 only includes PTAT components based on V_{PTAT} when generating V_{INT}, such that the bias voltage V_{BIAS} is proportional to absolute temperature. However, to prevent the LNA current I_LNA dropping below the threshold current I_{THRESH} as the temperature falls, the bias voltage V_{BIAS} is modified by the slope setting circuit 1300 when the temperature falls below the threshold temperature T_{THRESH}. In the fourth plot shown in FIG. 4B, the digital control signals are modified when the temperature drops below T_{THRESH} such that the slope setting circuit 1300 includes both components that are constant with temperature based on V_{CONSTANT} and components that are proportional to absolute temperature based on V_{PTAT} when generating V_{INT}. The proportion of PTAT components that are used to generate V_{INT} by the slope setting circuit 1300 are chosen such that the gradient of the V_{INT} (and thus V_{BIAS} and I_LNA) with respect to temperature is lower (having a smaller rate of change with respect to temperature) compared to the gradient when above the threshold temperature T_{THRESH} (where a PTAT bias voltage is used). Thus as shown by the fourth plot, the shallow gradient prevents the LNA current I_LNA from dropping too low (i.e. below the threshold current I_{THRESH}), and thus prevents the associated IIP3 and linearity limitations.

In some embodiments, the digital control signals for the slope setting circuit 1300 may be chosen such that the slope setting circuit 1300 only uses temperature constant components based on V_{CONSTANT} to generate V_{INT} when the temperature falls below the threshold temperature value T_{THRESH}. The bias voltage V_{BIAS} and therefore the value of the LNA current I_LNA would then also be constant with temperature when below the threshold temperature value T_{THRESH}.

In this way, the slope setting circuit 1300 can set the temperature dependence of the bias voltage V_{BIAS} based on the present temperature of the LNA, and modify the slope (gradient) of the bias voltage when the temperature falls below the threshold temperature value T_{THRESH}. In particular, the slope setting circuit can switch from the PTAT regime to a bias voltage that is constant with temperature, or includes both PTAT and constant with temperature components, when the temperature and thus current fall below threshold values where IIP3 is negatively impacted. This switch may be performed solely based on the detected temperature, or may be performed by taking into account both the present temperature and the present gain mode of the LNA (i.e. each gain mode has its own associated threshold temperature value).

FIG. 15 shows a slope setting circuit 1500 according to another embodiment. The slope setting circuit 1500 is identical to the slope setting circuit 1300 of FIG. 13, except that instead of the outputs (I_{O_CONSTANT} and I_{O_PTAT}) of the first and second current mirrors 1310,1312 being combined to form a combined current I_{O}, only one of the outputs (I_{O_CONSTANT} and I_{O_PTAT}) of the first and second current mirrors 1310,1312 is selected and used to generate V_{INT}.

Specifically, the slope setting circuit 1500 includes a first switch 1502 and a second switch 1504, both being FETs in the present embodiment. The slope setting circuit 1500 further includes an input for a slope control signal SLOPE, which is fed into the gate of one of the first and second switches 1502,1504, and is also fed into the gate of the other of the first and second switches 1502,1504 but via an inverter 1506. In this way, the slope control signal biases on only one of the first and second switches 1502,1504, meaning only one of the currents I_{O_CONSTANT} or I_{O_PTAT} is transferred to the output unit 1318 to form V_{INT}.

Thus in the embodiment of the slope setting circuit 1500 of FIG. 15, V_{INT} and thus V_{BIAS} may include only PTAT components or temperature constant components, rather than a mixture of both components. The slope control signal SLOPE is thus a switching control signal between the constant and PTAT regimes, and may effect a switch between the constant with temperature and PTAT modes either when the gain mode of the LNA is changed, or the temperature falls below/increases above the threshold temperature value.

It is to be understood that the specific circuit configurations of FIGS. 5A to 15 are for exemplary purposes only, and various other circuit configurations may be used to generate and control the biasing signal for the LNA according to the techniques discussed in relation to FIG. 14B.

Further, although the above described embodiments combine a constant with temperature voltage V_{CONSTANT} with the proportional to temperature voltage V_{PTAT}, in other embodiments a complementary with temperature voltage on V_{CTAT} could be used in place to the constant with temperature voltage V_{CONSTANT}. In general, any voltage including constant with temperature components and/or complementary with temperature components may be used instead of V_{CONSTANT} in the above described embodiments.

Further, although the above described embodiments discuss voltage signals such as V_{PTAT}, V_{CONSTANT}, V_{INT} and current signals such as I_{REF} and I_{O_CONSTANT}, it is to be understood in general that voltage signals and current signals may be used interchangeably, depending on the specific circuit configuration being used. Put another way, functionally equivalent circuit architectures could be implemented using either voltages or currents.

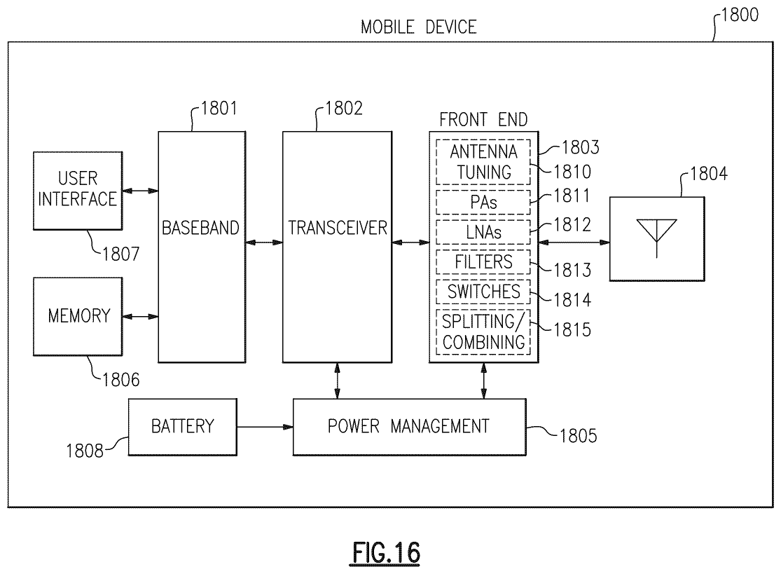

FIG. 16 is a schematic diagram of one embodiment of a mobile device 1800. The mobile device 1800 includes a baseband system 1801, a transceiver 1802, a front end system 1803, antennas 1804, a power management system 1805, a memory 1806, a user interface 1807, and a battery 1808.

The mobile device 1800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 1802 generates RF signals for transmission and processes incoming RF signals received from the antennas 1804. It will be understood that various functionalities associated with the transmission and receiving of RF signals can be achieved by one or more components that are collectively represented in FIG. 16 as the transceiver 1802. In one example, separate components (for instance, separate circuits or dies) can be provided for handling certain types of RF signals.

The front end system 1803 aids in conditioning signals transmitted to and/or received from the antennas 1804. In the illustrated embodiment, the front end system 1803 includes antenna tuning circuitry 1810, power amplifiers (PAs) 1811, low noise amplifiers (LNAs) 1812, filters 1813, switches 1814, and signal splitting/combining circuitry 1815. However, other implementations are possible. The LNAs 1812 can include one or more LNAs implemented in accordance with the teachings herein.

The front end system 1803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 1804 can include antennas used for a wide variety of types of communications. For example, the antennas 1804 can include antennas for transmitting and/or receiving signals associated with a wide variety of frequencies and communications standards.

In certain implementations, the antennas 1804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1800 can operate with beamforming in certain implementations. For example, the front end system 1803 can include amplifiers having controllable gain and phase shifters having controllable phase to provide beam formation and directivity for transmission and/or reception of signals using the antennas 1804. For example, in the context of signal transmission, the amplitude and phases of the transmit signals provided to the antennas 1804 are controlled such that radiated signals from the antennas 1804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 1804 from a particular direction. In certain implementations, the antennas 1804 include one or more arrays of antenna elements to enhance beamforming.

The baseband system 1801 is coupled to the user interface 1807 to facilitate processing of various user input and output (I/O), such as voice and data. The baseband system 1801 provides the transceiver 1802 with digital representations of transmit signals, which the transceiver 1802 processes to generate RF signals for transmission. The baseband system 1801 also processes digital representations of received signals provided by the transceiver 1802. As shown in FIG. 16, the baseband system 1801 is coupled to the memory 1806 of facilitate operation of the mobile device 1800.

The memory 1806 can be used for a wide variety of purposes, such as storing data and/or instructions to facilitate the operation of the mobile device 1800 and/or to provide storage of user information.

The power management system 1805 provides a number of power management functions of the mobile device 1800. In certain implementations, the power management system 1805 includes a PA supply control circuit that controls the supply voltages of the power amplifiers 1811. For example, the power management system 1805 can be configured to change the supply voltage(s) provided to one or more of the power amplifiers 1811 to improve efficiency, such as power added efficiency (PAE).

As shown in FIG. 16, the power management system 1805 receives a battery voltage from the battery 1808. The battery 1808 can be any suitable battery for use in the mobile device 1800, including, for example, a lithium-ion battery.

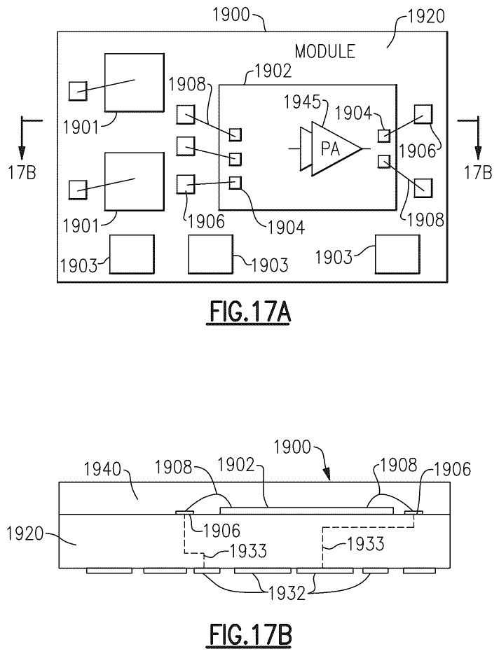

FIG. 17A is a schematic diagram of one embodiment of a packaged module 1900. FIG. 17B is a schematic diagram of a cross-section of the packaged module 1900 of FIG. 17A taken along the lines 17B-17B.

The packaged module 1900 includes radio frequency components 1901, a semiconductor die 1902, surface mount devices 1903, wirebonds 1908, a package substrate 1920, and an encapsulation structure 1940. The package substrate 1920 includes pads 1906 formed from conductors disposed therein. Additionally, the semiconductor die 1902 includes pins or pads 1904, and the wirebonds 1908 have been used to connect the pads 1904 of the die 1902 to the pads 1906 of the package substrate 1920.

The semiconductor die 1902 includes a low noise amplifier 1945, which can be implemented in accordance with one or more features disclosed herein.

The packaging substrate 1920 can be configured to receive a plurality of components such as radio frequency components 1901, the semiconductor die 1902 and the surface mount devices 1903, which can include, for example, surface mount capacitors and/or inductors. In one implementation, the radio frequency components 1901 include integrated passive devices (IPDs).

As shown in FIG. 17B, the packaged module 1900 is shown to include a plurality of contact pads 1932 disposed on the side of the packaged module 1900 opposite the side used to mount the semiconductor die 1902. Configuring the packaged module 1900 in this manner can aid in connecting the packaged module 1900 to a circuit board, such as a phone board of a mobile device. The example contact pads 1932 can be configured to provide radio frequency signals, bias signals, and/or power (for example, a power supply voltage and ground) to the semiconductor die 1902 and/or other components. As shown in FIG. 17B, the electrical connections between the contact pads 1932 and the semiconductor die 1902 can be facilitated by connections 1933 through the package substrate 1920. The connections 1933 can represent electrical paths formed through the package substrate 1920, such as connections associated with vias and conductors of a multilayer laminated package substrate.

In some embodiments, the packaged module 1900 can also include one or more packaging structures to, for example, provide protection and/or facilitate handling. Such a packaging structure can include overmold or encapsulation structure 1940 formed over the packaging substrate 1920 and the components and die(s) disposed thereon.

It will be understood that although the packaged module 1900 is described in the context of electrical connections based on wirebonds, one or more features of the present disclosure can also be implemented in other packaging configurations, including, for example, flip-chip configurations.

### Applications

The principles and advantages of the embodiments herein can be used for any other systems or apparatus that have needs for low noise amplification. Examples of such apparatus include RF communication systems. RF communications systems include, but are not limited to, mobile phones, tablets, base stations, network access points, customer-premises equipment (CPE), laptops, and wearable electronics. Thus, the low noise amplifiers herein can be included in various electronic devices, including, but not limited to, consumer electronic products.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the disclosure. The accompanying claims and their equivalents are intended to cover such forms or modifications as would fall within the scope of the disclosure.

What is claimed is:

1. A low noise amplifier circuit comprising:
at least one amplification transistor configured to amplify a radio frequency input signal;
a slope setting circuit configured to generate an intermediate voltage based on a gain mode of the low noise amplifier circuit, the intermediate voltage having a first gradient and being proportional to absolute temperature when the low noise amplifier circuit is in a first gain mode, and the intermediate voltage having a rate of change with respect to temperature smaller than the first gradient when the low noise amplifier circuit is in a second gain mode, the second gain mode having a lower gain than the first gain mode; and
a biasing circuit configured to generate a bias voltage for the at least one amplification transistor based on the intermediate voltage.

2. The low noise amplifier circuit of claim 1 wherein the intermediate voltage sets a temperature dependence of the bias voltage.

3. The low noise amplifier circuit of claim 1 wherein the intermediate voltage is constant with respect to temperature when the low noise amplifier circuit is in the second gain mode.

4. The low noise amplifier circuit of claim 1 wherein the slope setting circuit receives at a first input a first voltage that is proportional to absolute temperature and receives at a second input a second voltage that is constant with respect to temperature.

5. The low noise amplifier circuit of claim 4 wherein the intermediate voltage is based on the first voltage when the low noise amplifier circuit is in the first gain mode.

6. The low noise amplifier circuit of claim 4 wherein the intermediate voltage is based on the first voltage and the second voltage or a combination of the first voltage and the second voltage when the low noise amplifier circuit is in the second gain mode.

7. The low noise amplifier circuit of claim 1 wherein the first gain mode is a gain mode in which a current passing through the at least one amplification transistor of the low noise amplifier circuit remains above a threshold current value within an operating temperature range of the low noise amplifier circuit when biased by a proportional to absolute temperature bias signal.

8. The low noise amplifier circuit of claim 1 wherein the second gain mode is a gain mode in which a current passing through the at least one amplification transistor of the low noise amplifier circuit falls below a threshold current value within an operating temperature range of the low noise amplifier circuit if biased by a proportional to absolute temperature bias signal.

9. The low noise amplifier circuit of claim 1 wherein the second gain mode is a gain mode in which amplification of the radio frequency input signal caused by the low noise amplifier circuit is between 0 and 5 dB.

10. The low noise amplifier circuit of claim 1 wherein the first gain mode is a gain mode in which amplification of the radio frequency input signal caused by the low noise amplifier circuit is above 5 dB.

11. The low noise amplifier circuit of claim 1 wherein a present gain mode of the low noise amplifier circuit is controlled by a gain control signal input into the biasing circuit.

12. The low noise amplifier circuit of claim 1 wherein a change in a present gain mode of the low noise amplifier circuit is communicated to the slope setting circuit to adjust a switching mode in the slope setting circuit.

13. A mobile device comprising:
an antenna; and
a front-end system that includes a low noise amplifier circuit including: at least one amplification transistor configured to amplify a radio frequency input signal; a slope setting circuit configured to generate an intermediate voltage based on a gain mode of the low noise amplifier circuit, the intermediate voltage having a first gradient and being proportional to absolute temperature when the low noise amplifier circuit is in a first gain mode, and the intermediate voltage having a rate of change with respect to temperature smaller than the first gradient when the low noise amplifier circuit is in a second gain mode, the second gain mode having a lower gain than the first gain mode;
and a biasing circuit configured to generate a bias voltage for the at least one amplification transistor based on the intermediate voltage.

14. The mobile device of claim 13 wherein the intermediate voltage sets a temperature dependence of the bias voltage.

15. A method of biasing a low noise amplifier circuit, comprising:
generating a bias voltage signal that is proportional to absolute temperature with a first gradient when the low noise amplifier circuit is in a first gain mode;
generating a bias voltage signal having a rate of change with respect to temperature smaller than the first gradient when the low noise amplifier circuit is in a second gain mode, the second gain mode having a lower gain than the first gain mode;
inputting the bias voltage signal into a gate terminal of an amplification transistor in the low noise amplifier circuit.

16. The method of claim 15 wherein generating the bias voltage signal includes generating an intermediate voltage and setting a temperature dependence of the bias voltage signal based on the intermediate voltage.

17. The method of claim 15 wherein the generated bias voltage signal is constant with respect to temperature when the low noise amplifier circuit is in the second gain mode.

18. The method of claim 15 wherein the first gain mode is a gain mode in which a current passing through the amplification transistor of the low noise amplifier circuit remains above a threshold current value within an operating temperature range of the low noise amplifier circuit when biased by a proportional to absolute temperature bias signal.

19. The method of claim 15 wherein the second gain mode is a gain mode in which a current passing through the amplification transistor of the low noise amplifier circuit falls below a threshold current value within an operating temperature range of the low noise amplifier circuit if biased by a proportional to absolute temperature bias signal.

20. The method of claim 15 wherein the second gain mode is a gain mode in which amplification of a radio frequency input signal caused by the low noise amplifier circuit is between 0 and 5 dB.
